(19) United States
(12) Patent Application Publication
(10) Pub. No.: US 2022/0399072 A1
(43) Pub. Date: Dec. 15, 2022

(54) NONVOLATILE MEMORY WITH LATCH SCRAMBLE

(71) Applicant: SanDisk Technologies LLC, Addison, CA (US)

(72) Inventors: Hua-Ling Cynthia Hsu, Fremont, CA (US); Dana Lee, Saratoga, CA (US)

(73) Assignee: SanDisk Technologies LLC, Addison, TX (US)

(21) Appl. No.: 17/347,953

(22) Filed: Jun. 15, 2021

(51) Int. Cl. G11C 29/42; G11C 29/00; G11C 7/10; G11C 16/10; G11C 16/26

(52) U.S. Cl. CPC G11C 29/42; G11C 29/789; G11C 7/106; G11C 7/1087; G11C 16/102; G11C 16/26; G11C 2029/1202

(57) ABSTRACT

An apparatus includes one or more control circuits configured to connect to a plurality of non-volatile memory cells arranged along word lines. The one or more control circuits are configured to receive a plurality of encoded portions of data to be programmed in non-volatile memory cells of a target word line, each encoded portion of data encoded according to an Error Correction Code (ECC) encoding scheme, and arrange the plurality of encoded portions of data in a plurality of rows of data latches corresponding to a plurality of logical pages such that each encoded portion of data is distributed across two or more rows of data latches. The one or more control circuits are also configured to program the distributed encoded portions of data from the plurality of rows of data latches into non-volatile memory cells along a target word line.

### BACKGROUND

Semiconductor memory is widely used in various electronic devices such as cellular telephones, digital cameras, personal digital assistants, medical electronics, mobile computing devices, non-mobile computing devices and data servers. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory), Electrically Erasable Programmable Read-Only Memory (EEPROM), and others. Some memory cells store information by storing a charge in a charge storage region. Other memory cells store information using other techniques, such as by the resistance of the memory cell. Some memories store one bit per cell using two data states (Single Level Cell or SLC) while others store more than one bit per cell using more than two data states (Multi Level Cell or MLC, which may store two bits per cell). Storing four bits per cell may use sixteen data states (Quad Level Cell or QLC).

When a memory system is deployed in or connected to an electronic device (the host), the memory system can be used to store data and read data. Errors may occur in data that is read from memory. Error Correction Code (ECC) may be used to encode data prior to storage and decode data when it is read. ECC allows some errors (e.g., up to a limit) to be corrected.

### BRIEF DESCRIPTION OF THE DRAWINGS

Like-numbered elements refer to common components in the different Figures.

FIG. 1A is a block diagram of one embodiment of a memory system connected to a host.

FIG. 1B is a block diagram of one embodiment of a Front-End Processor Circuit.

In some embodiments, the Front-End Processor Circuit is part of a Controller.

FIG. 1C is a block diagram of one embodiment of a Back End Processor Circuit.

In some embodiments, the Back End Processor Circuit is part of a Controller.

FIG. 1D is a block diagram of one embodiment of a memory package.

FIG. 2A is a functional block diagram of an embodiment of a memory die.

FIG. 2B is a functional block diagram of an embodiment of an integrated memory assembly.

FIG. 3 is a perspective view of a portion of one embodiment of a monolithic three-dimensional memory structure.

FIG. 4A is a block diagram of a memory structure having two planes.

FIG. 4B depicts a top view of a portion of a block of memory cells.

FIG. 4C depicts a cross sectional view of a portion of a block of memory cells.

FIG. 5 shows an example of a sense block.

FIG. 6 shows multiple data states of nonvolatile memory cells.

FIGS. 7A-B illustrate an example of sixteen data states storing four bits per cell.

FIG. 8 illustrates an example of storing encoded portions of data.

FIGS. 9A-E illustrate examples of latching and programming encoded portions of data.

FIGS. 10A-E illustrate examples of scrambling data in data latches.

FIG. 11 is an example timing diagram showing transfer, latching, and scrambling of data.

FIGS. 12A-E show an example implementation of scrambling in a plane.

FIGS. 13A-F show another example implementation of scrambling in a plane.

FIGS. 14A-E show another example implementation of scrambling in a plane.

FIGS. 15A-B illustrate serial scrambling of data.

FIGS. 16A-B illustrate parallel scrambling of data.

FIG. 17 is an example timing diagram showing scrambling data as it is received.

FIGS. 18A-D illustrate an example of reading scrambled data.

FIGS. 19A-C illustrate an example implementation in Three Level Cell (TLC) non-volatile memory.

FIG. 20 illustrates an example of a method that includes scrambling encoded portions of data.

### DETAILED DESCRIPTION

Techniques are disclosed herein to enable encoded portions of data to be distributed among two or more logical pages that are programmed together in non-volatile memory cells along a word line. This may result in more uniform distribution of errors across encoded portions of data so that decoding encoded portions is more uniform.

In some cases, data is stored in non-volatile memory cells in multiple logical pages. Different logical pages of the same word line may have different error rates (e.g., because they are differently affected by various phenomena). For example, an upper page may have a higher error rate than a lower page. When encoded portions of data are assigned to logical pages in a one-to-one assignment, some encoded portions have higher error rates because of their logical page assignment (e.g., an encoded portion assigned to an upper page may have a higher error rate than an encoded portion assigned to a lower page). According to examples described below, encoded portions of data may be scrambled prior to programming so that encoded portions are distributed among two or more logical pages. An encoded portion may be divided into two or more parts (e.g., parts of equal size corresponding to two or more planes) and different parts may be assigned to different logical pages. Such scrambling may be performed as encoded portions are received or may occur after data is loaded into latches for programming. For example, encoded portions may initially be arranged with one encoded portion per row of data latches for programming to a corresponding logical page and may be scrambled within the latches so that different parts of an encoded portion are in different rows of data latches. Subsequently, parts of different encoded portions are programmed together from a row of data latches in a logical page. In this way, errors associated with a logical page affect parts of different encoded portions and are not concentrated in any one encoded portion. When data is read and encoded portions are decoded, error rates are generally similar between encoded portions (e.g., error rates may be averaged between upper and lower logical pages).

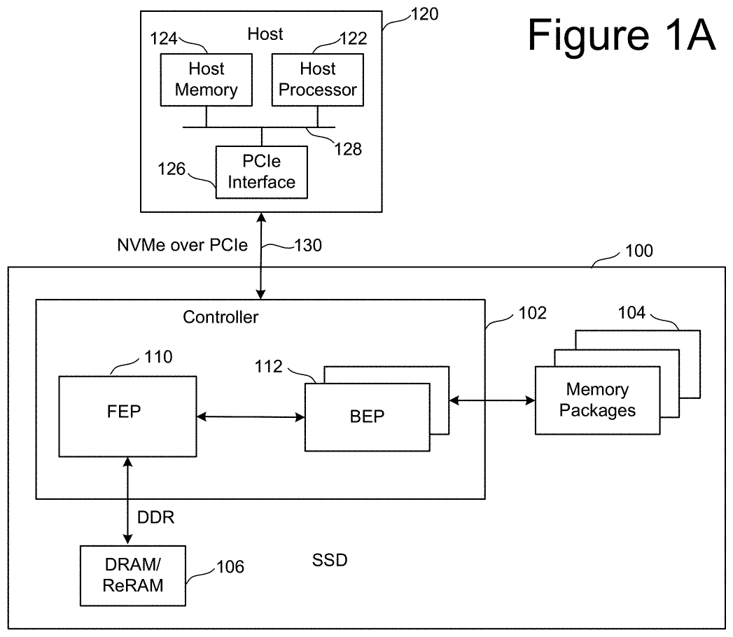

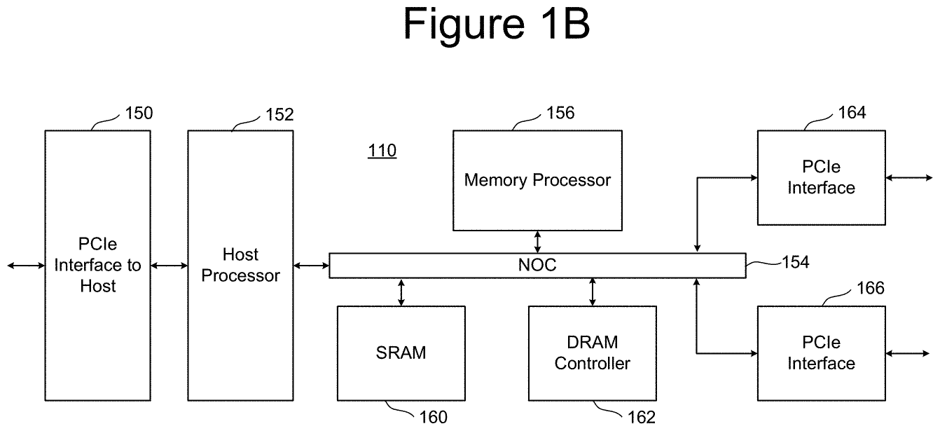

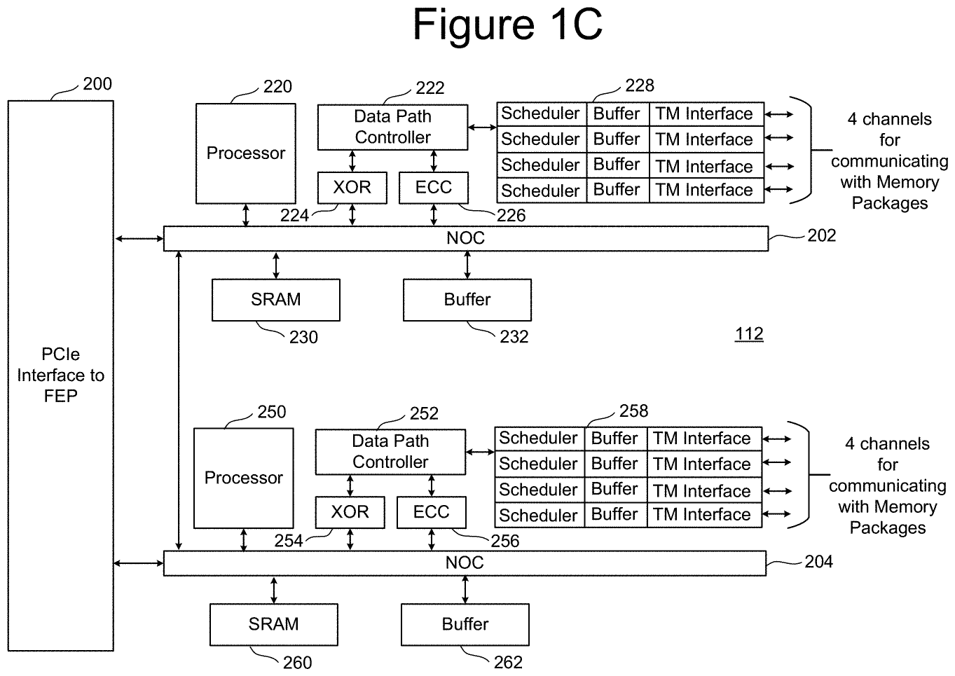

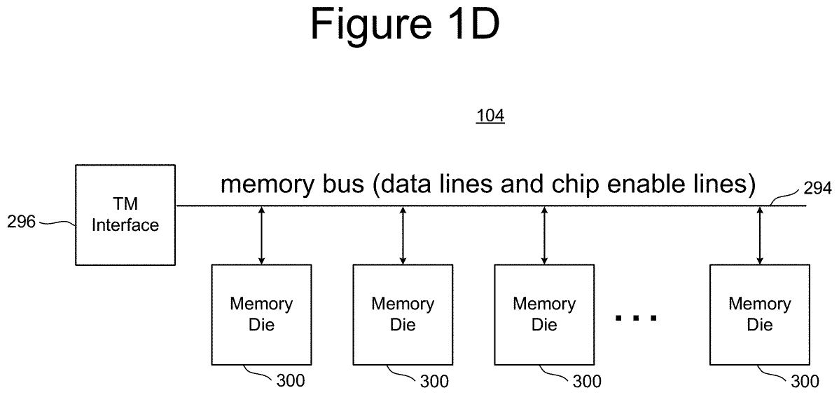

FIG. 1A is a block diagram of one embodiment of a memory system 100 connected to a host 120. Memory system 100 can implement the technology proposed herein. Many different types of memory systems can be used with the technology proposed herein. One example memory system is a solid-state drive (“SSD”); however, other types of memory systems can also be used. Memory system 100 comprises a Controller 102, non-volatile memory 104 for storing data, and local memory (e.g., DRAM/ReRAM) 106. Controller 102 comprises a Front-End Processor Circuit (FEP) 110 and one or more Back End Processor Circuits (BEP) 112. In one embodiment FEP circuit 110 is implemented on an ASIC. In one embodiment, each BEP circuit 112 is implemented on a separate ASIC. The ASICs for each of the BEP circuits 112 and the FEP circuit 110 are implemented on the same semiconductor such that the Controller 102 is manufactured as a System on a Chip (“SoC”). FEP 110 and BEP 112 both include their own processors. In one embodiment, FEP circuit 110 and BEP 112 work as a master slave configuration where the FEP circuit 110 is the master and each BEP 112 is a slave. For example, FEP circuit 110 implements a flash translation layer that performs memory management (e.g., garbage collection, wear leveling, etc.), logical to physical address translation, communication with the host, management of DRAM (local volatile memory) and management of the overall operation of the SSD (or other non-volatile storage system). The BEP circuit 112 manages memory operations in the memory packages/die at the request of FEP circuit 110. For example, the BEP circuit 112 can carry out the read, erase and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages. Controller 102 is one example of a control circuit.

In one embodiment, non-volatile memory 104 comprises a plurality of memory packages. Each memory package includes one or more memory die. Therefore, Controller 102 is connected to one or more non-volatile memory die. In one embodiment, each memory die in the memory packages 14 utilize NAND flash memory (including two-dimensional NAND flash memory and/or three-dimensional NAND flash memory). In other embodiments, the memory package can include other types of memory.

Controller 102 communicates with host 120 via an interface 130 that implements NVM Express (NVMe) over PCI Express (PCIe). For working with memory system 100, host 120 includes a host processor 122, host memory 124, and a PCIe interface 126 connected to bus 128. Host memory 124 is the host's physical memory, and can be DRAM, SRAM, non-volatile memory or another type of storage. Host 120 is external to and separate from memory system 100. In one embodiment, memory system 100 is embedded in host 120.

FIG. 1B is a block diagram of one embodiment of FEP circuit 110. FIG. 1B shows a PCIe interface 150 to communicate with host 120 and a host processor 152 in communication with that PCIe interface. The host processor 152 can be any type of processor known in the art that is suitable for the implementation. Host processor 152 is in communication with a network-on-chip (NOC) 154. A NOC is a communication subsystem on an integrated circuit, typically between cores in a SoC. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, SRAM 160 and a DRAM controller 162. The DRAM controller 162 is used to operate and communicate with the DRAM (e.g., DRAM 106). SRAM 160 is local RAM memory used by memory processor 156. Memory processor 156 is used to run the FEP circuit and perform the various memory operations. Also, in communication with the NOC are two PCIe Interfaces 164 and 166. In the embodiment of FIG. 1B, the SSD controller will include two BEP circuits 112; therefore, there are two PCIe Interfaces 164/166. Each PCIe Interface communicates with one of the BEP circuits 112. In other embodiments, there can be more or less than two BEP circuits 112; therefore, there can be more than two PCIe Interfaces.

FIG. 1C is a block diagram of one embodiment of the BEP circuit 112. FIG. 1C shows a PCIe Interface 200 for communicating with the FEP circuit 110 (e.g., communicating with one of PCIe Interfaces 164 and 166 of FIG. 1B). PCIe Interface 200 is in communication with two NOCs 202 and 204. In one embodiment the two NOCs can be combined to one large NOC. Each NOC (202/204) is connected to SRAM (230/260), a buffer (232/262), processor (220/250), and a data path controller (222/252) via an XOR engine (224/254) and an ECC engine (226/256). The ECC engines 226/256 are used to perform error correction, as known in the art. The XOR engines 224/254 are used to XOR the data so that data can be combined and stored in a manner that can be recovered in case there is a programming error. Data path controller 22 is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer and TM Interface for each of the channels. The processor can be any standard processor known in the art. The data path controllers 222/252 can be a processor, FPGA, microprocessor or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

FIG. 1D is a block diagram of one embodiment of a memory package 104 that includes a plurality of memory die 300 connected to a memory bus 294 (data lines and chip enable lines). The memory bus 294 connects to a Toggle Mode Interface 296 for communicating with the TM Interface of a BEP circuit 112 (see e.g., FIG. 1C). In some embodiments, the memory package can include a small controller connected to the memory bus and the TM Interface. The memory package can have one or more memory die. In one embodiment, each memory package includes eight or 16 memory die; however, other numbers of memory die can also be implemented. The technology described herein is not limited to any particular number of memory die.

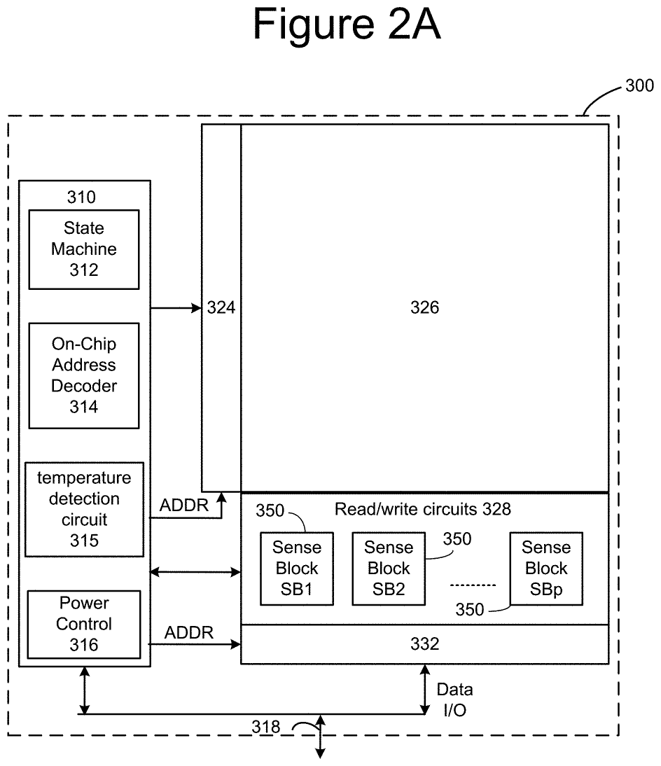

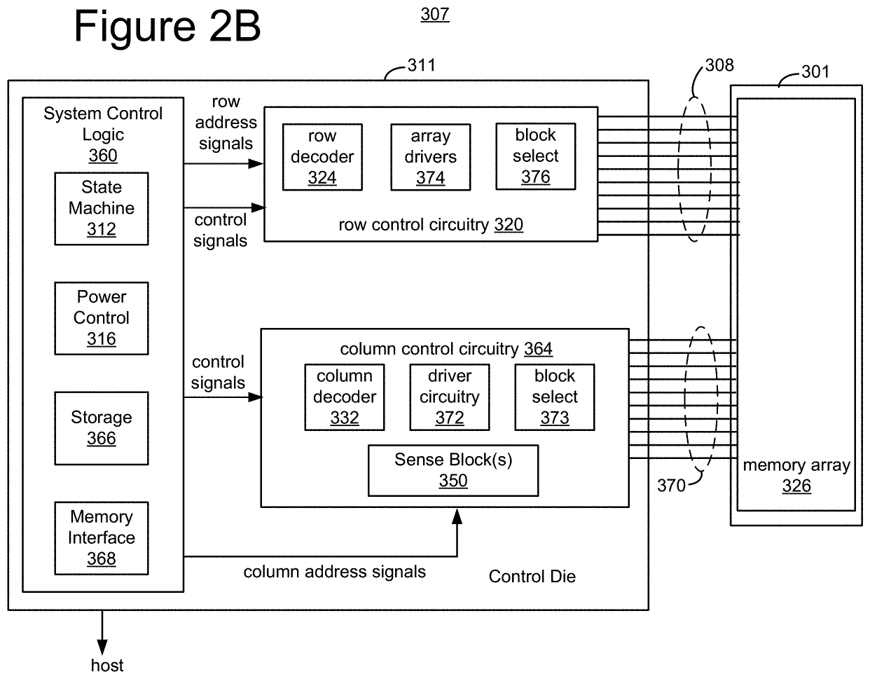

FIG. 2A is a functional block diagram of one embodiment of a memory die 300. Each of the one or more memory die 300 of FIG. 1D can be implemented as memory die 300 of FIG. 2. The components depicted in FIG. 2 are electrical circuits. In one embodiment, each memory die 300 includes a memory structure 326, control circuits 310, and read/write circuits 328, all of which are electrical circuits. Memory structure 326 is addressable by word lines via a row decoder 324 and by bit lines via a column decoder 332. The read/write circuits 328 include multiple sense blocks 350 including SB1, SB2, . . . ,SBp (sensing circuits) and allow a page (or multiple pages) of data in multiple memory cells to be read or programmed in parallel. In one embodiment, each sense block includes a sense amplifier and a set of latches connected to the bit line. The latches store data to be written and/or data that has been read. The sense blocks include bit line drivers.

Commands and data are transferred between the controller and the memory die 300 via lines 318, which may form a bus between memory die 300 and the controller (e.g., memory bus 294). In one embodiment, memory die 300 includes a set of input and/or output (I/O) pins that connect to lines 318.

Control circuits 310 cooperate with the read/write circuits 328 to perform memory operations (e.g., write, read, erase, and others) on memory structure 326. In one embodiment, control circuits 310 includes a state machine 312, an on-chip address decoder 314, a power control module 316 (power control circuit) and a temperature detection circuit 315. State machine 312 provides die-level control of memory operations. In one embodiment, state machine 312 is programmable by software. In other embodiments, state machine 312 does not use software and is completely implemented in hardware (e.g., electrical circuits). In some embodiments, state machine 312 can be replaced by a microcontroller or microprocessor. In one embodiment, control circuits 310 includes buffers such as registers, ROM fuses and other storage devices for storing default values such as base voltages and other parameters.

The on-chip address decoder 314 provides an address interface between addresses used by controller 102 to the hardware address used by the decoders 324 and 332. Power control module 316 controls the power and voltages supplied to the word lines and bit lines during memory operations. Power control module 316 may include charge pumps for creating voltages.

For purposes of this document, control circuits 310, alone or in combination with read/write circuits 328 and decoders 324/332, comprise one or more control circuits for memory structure 326. These one or more control circuits are electrical circuits that perform the functions described below in the flow charts and signal diagrams. In other embodiments, the one or more control circuits can consist only of controller 102, which is an electrical circuit in combination with software, that performs the functions described below in the flow charts and signal diagrams. In another alternative, the one or more control circuits comprise controller 102 and control circuits 310 performing the functions described below in the flow charts and signal diagrams. In another embodiment, the one or more control circuits comprise state machine 312 (or a microcontroller or microprocessor) alone or in combination with controller 102.

In one embodiment, memory structure 326 comprises a monolithic three-dimensional memory array of non-volatile memory cells in which multiple memory levels are formed above a single substrate, such as a wafer. The memory structure may comprise any type of non-volatile memory that is monolithically formed in one or more physical levels of arrays of memory cells having an active area disposed above a silicon (or other type of) substrate. In one example, the non-volatile memory cells of memory structure 326 comprise vertical NAND strings with charge-trapping material such as described, for example, in U.S. Pat. No. 9,721,662, incorporated herein by reference in its entirety. In another embodiment, memory structure 326 comprises a two-dimensional memory array of non-volatile memory cells. In one example, the non-volatile memory cells are NAND flash memory cells utilizing floating gates such as described, for example, in U.S. Pat. No. 9,082,502, incorporated herein by reference in its entirety. Other types of memory cells (e.g., NOR-type flash memory) can also be used.

In one embodiment, the control circuit(s) (e.g., control circuits 310) are formed on a first die, referred to as a control die, and the memory array (e.g., memory structure 326) is formed on a second die, referred to as a memory die. For example, some or all control circuits (e.g., control circuit 310, row decoder 324, column decoder 332, and read/write circuits 328) associated with a memory may be formed on the same control die. A control die may be bonded to one or more corresponding memory die to form an integrated memory assembly. The control die and the memory die may have bond pads arranged for electrical connection to each other. Bond pads of the control die and the memory die may be aligned and bonded together by any of a variety of bonding techniques, depending in part on bond pad size and bond pad spacing (i.e., bond pad pitch). In some embodiments, the bond pads are bonded directly to each other, without solder or other added material, in a so-called Cu-to-Cu bonding process. In some examples, dies are bonded in a one-to-one arrangement (e.g., one control die to one memory die). In some examples, there may be more than one control die and/or more than one memory die in an integrated memory assembly. In some embodiments, an integrated memory assembly includes a stack of multiple control die and/or multiple memory die. In some embodiments, the control die is connected to, or otherwise in communication with, a memory controller. For example, a memory controller may receive data to be programmed into a memory array. The memory controller will forward that data to the control die so that the control die can program that data into the memory array on the memory die.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 307. One or more integrated memory assemblies 307 may be used in a memory package 104 in storage system 100. The integrated memory assembly 307 includes two types of semiconductor die (or more succinctly, “die”). Memory die 301 includes memory array 326 (memory structure). Memory array 326 may contain non-volatile memory cells.

Control die 311 includes column control circuitry 364, row control circuitry 320 and system control logic 360 (including state machine 312, power control module 316, storage 366, and memory interface 368). In some embodiments, control die 311 is configured to connect to the memory array 326 in the memory die 301. FIG. 2B shows an example of the peripheral circuitry, including control circuits, formed in a peripheral circuit or control die 311 coupled to memory array 326 formed in memory die 301. System control logic 360, row control circuitry 320, and column control circuitry 364 are located in control die 311. In some embodiments, all or a portion of the column control circuitry 364 and all or a portion of the row control circuitry 320 are located on the memory die 301. In some embodiments, some of the circuitry in the system control logic 360 is located on the on the memory die 301.

System control logic 360, row control circuitry 320, and column control circuitry 364 may be formed by a common process (e.g., CMOS process), so that adding elements and functionalities, such as ECC, more typically found on a memory controller 102 may require few or no additional process steps (i.e., the same process steps used to fabricate controller 102 may also be used to fabricate system control logic 360, row control circuitry 320, and column control circuitry 364). Thus, while moving such circuits from a die such as memory die 301 may reduce the number of steps needed to fabricate such a die, adding such circuits to a die such as control die 311 may not require many additional process steps.

FIG. 2B shows column control circuitry 364 including sense block(s) 350 on the control die 311 coupled to memory array 326 on the memory die 301 through electrical paths 370. For example, electrical paths 370 may provide electrical connection between column decoder 332, driver circuitry 372, and block select 373 and bit lines of memory array (or structure) 326. Electrical paths may extend from column control circuitry 364 in control die 311 through pads on control die 311 that are bonded to corresponding pads of the memory die 301, which are connected to bit lines of memory structure 326. Each bit line of memory structure 326 may have a corresponding electrical path in electrical paths 370, including a pair of bond pads, which connects to column control circuitry 364. Similarly, row control circuitry 320, including row decoder 324, array drivers 374, and block select 376 are coupled to memory array 326 through electrical paths 308. Each of electrical path 308 may correspond to a word line, dummy word line, or select gate line. Additional electrical paths may also be provided between control die 311 and memory structure die 301.

In some embodiments, there is more than one control die 311 and/or more than one memory die 301 in an integrated memory assembly 307. In some embodiments, the integrated memory assembly 307 includes a stack of multiple control die 311 and multiple memory structure die 301. In some embodiments, each control die 311 is affixed (e.g., bonded) to at least one of the memory structure dies 301.

The exact type of memory array architecture or memory cell included in memory structure 326 is not limited to the examples above. Many different types of memory array architectures or memory cell technologies can be used to form memory structure 326. No particular non-volatile memory technology is required for purposes of the new claimed embodiments proposed herein. Other examples of suitable technologies for memory cells of the memory structure 326 include ReRAM memories, magnetoresistive memory (e.g., MRAM, Spin Transfer Torque MRAM, Spin Orbit Torque MRAM), phase change memory (e.g., PCM), and the like. Examples of suitable technologies for architectures of memory structure 326 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

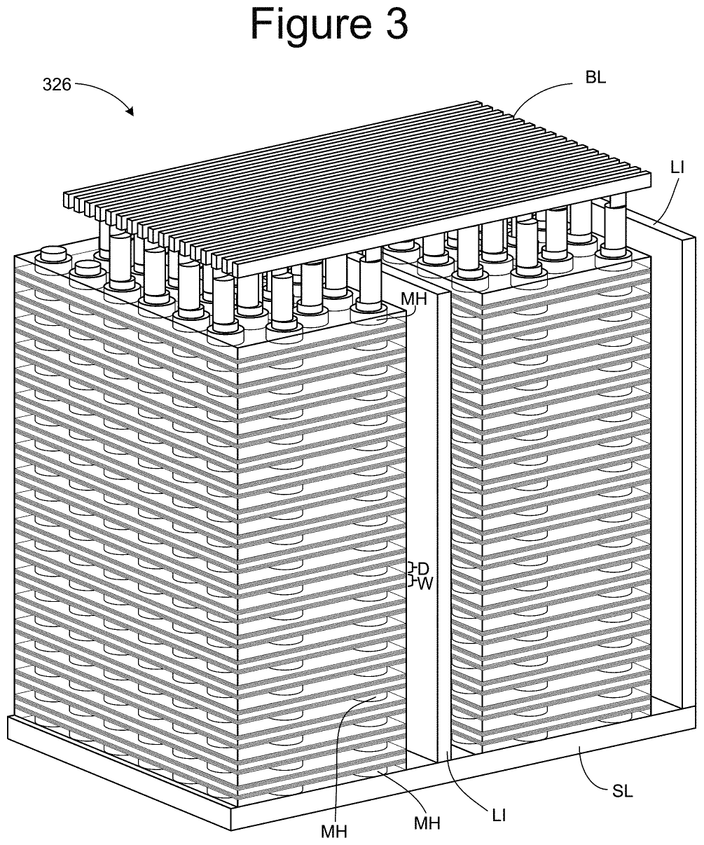

FIG. 3 is a perspective view of a portion of one example embodiment of a monolithic three-dimensional memory array that can comprise memory structure 326, which includes a plurality memory cells. For example, FIG. 3 shows a portion of one block of memory. The structure depicted includes a set of bit lines BL positioned above a stack of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. One set of embodiments includes between 108-278 alternating dielectric layers and conductive layers, for example, 127 data word line layers, 8 select layers, 4 dummy word line layers and 139 dielectric layers.

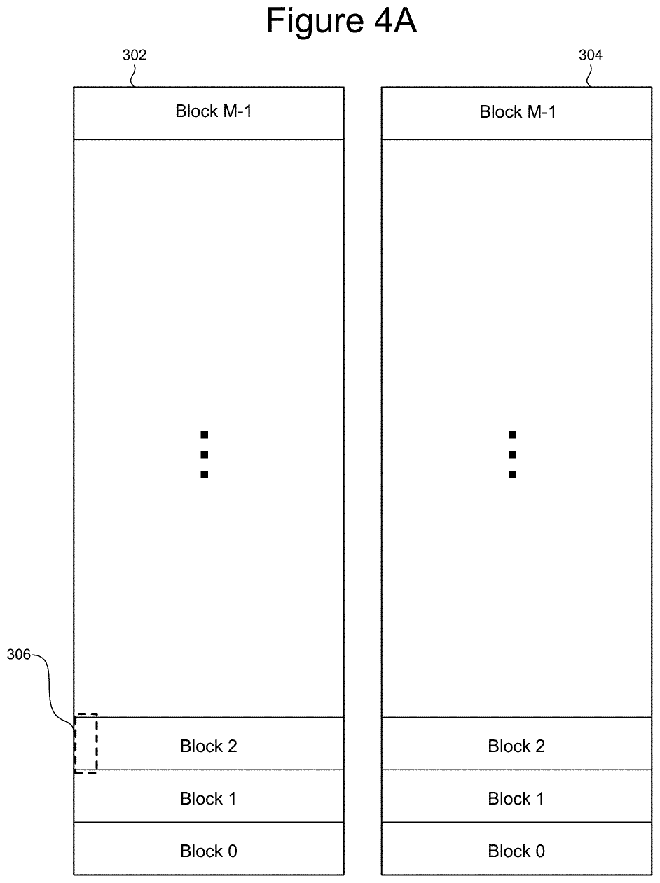

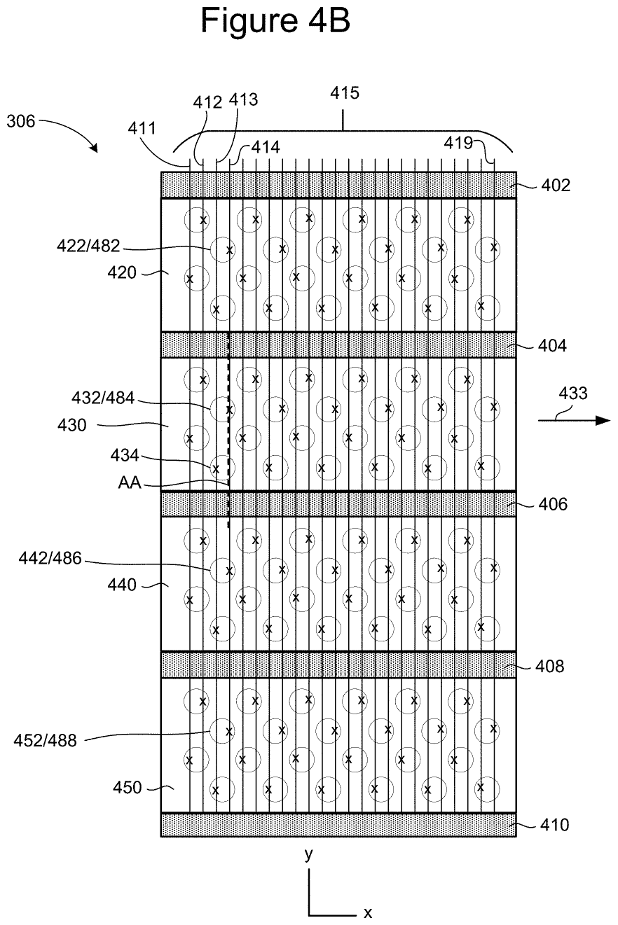

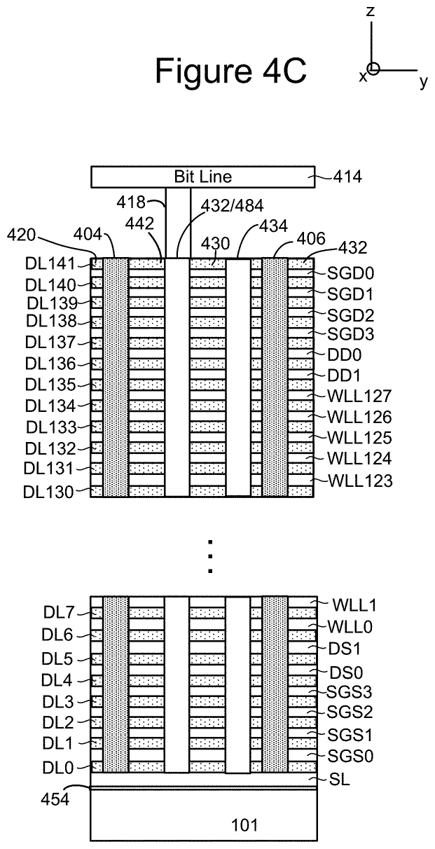

More or fewer than 108-278 layers can also be used. As will be explained below, the alternating dielectric layers and conductive layers are divided into four “fingers” by local interconnects LI. FIG. 3 shows two fingers and two local interconnects LI. Below and the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping layer to create a vertical column of memory cells. Each memory cell can store one or more bits of data. More details of the three-dimensional monolithic memory array that comprises memory structure 326 is provided below with respect to FIG. 4A-4C.

FIG. 4A is a block diagram explaining one example organization of memory structure 326, which is divided into two planes 302 and 304. Each plane is then divided into M blocks. In one example, each plane has about 2000 blocks. However, different numbers of blocks and planes can also be used. In on embodiment, a block of memory cells is a unit of erase. That is, all memory cells of a block are erased together. In other embodiments, memory cells can be grouped into blocks for other reasons, such as to organize the memory structure 326 to enable the signaling and selection circuits. In some embodiments, a block represents a groups of connected memory cells as the memory cells of a block share a common set of word lines.

FIGS. 4B-4C depict an example three dimensional (“3D”) NAND structure. FIG. 4B is a block diagram depicting a top view of a portion of one block from memory structure 326. The portion of the block depicted in FIG. 4B corresponds to portion 306 in block 2 of FIG. 4A. As can be seen from FIG. 4B, the block depicted in FIG. 4B extends in the direction of 433. In one embodiment, the memory array has sixty layers. Other embodiments have less than or more than sixty layers. However, FIG. 4B only shows the top layer.

FIG. 4B depicts a plurality of circles that represent the vertical columns. Each of the vertical columns include multiple select gates (also referred to as a select transistors) and multiple memory cells (also referred to as data memory cells). In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends in the direction of arrow 433, the block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the block is depicted. It is contemplated that more than twenty-four bit lines may be connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together at the end of the block to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of one embodiment of a three-dimensional memory structure 326 showing a cross-sectional view along line AA of FIG. 4B. This cross-sectional view cuts through vertical columns 432 and 434 and region 430 (see FIG. 4B). The structure of FIG. 4C includes four drain side select layers SGD0, SGD1, SGD2 and SGD3 associated with the drain side select gates; four source side select layers SGS0, SGS1, SGS2 and SGS3 associated with the source side select gates; four dummy word line layers DD0, DD1, DS0 and DS1; and forty-eight data word line layers WLL0-WLL127 for connecting to data memory cells. Other embodiments can implement more or less than four drain side select layers, more or less than four source side select layers, more or less than four dummy word line layers, and more or less than one hundred- and twenty-eight-word line layers. Vertical columns 432 and 434 are depicted protruding through the drain side select layers, source side select layers, dummy word line layers and word line layers. In one embodiment, each vertical column comprises a NAND string. For example, vertical column 432 comprises NAND string 484. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to bit line 414 via connector 418. Local interconnects 404 and 406 are also depicted.

For ease of reference, drain side select layers SGD0, SGD1, SGD2 and SGD3; source side select layers SGS0, SGS1, SGS2 and SGS3; dummy word line layers DD0, DD1, DS0 and DS1; and word line layers WLL0-WLL127 collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL141. For example, dielectric layers DL131 is above word line layer WLL123 and below word line layer WLL124. In one embodiment, the dielectric layers are made from SiO₂. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layers WLL0-WLL127 connect to memory cells (also called data memory cells). Dummy word line layers DD0, DD1, DS0 and DS1 connect to dummy memory cells. A dummy memory cell does not store host data (data provided from the host, such as data from a user of the host), while a data memory cell is eligible to store host data. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

Although the example memory system of FIGS. 3-4C is a three-dimensional memory structure that includes vertical NAND strings with charge-trapping material, other (2D and 3D) memory structures can also be used with the technology described herein.

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate.

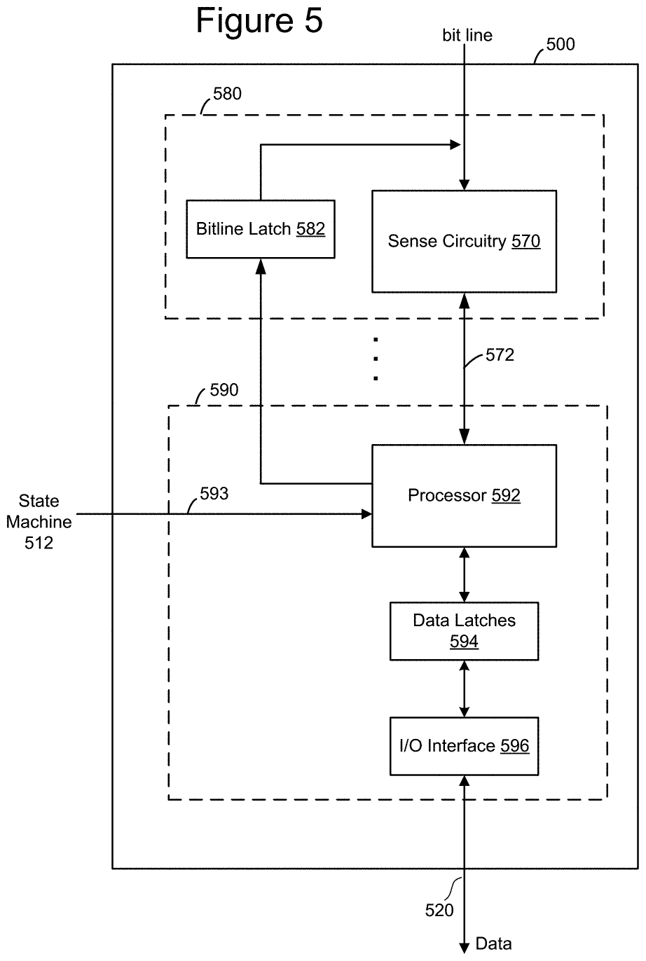

FIG. 5 depicts one embodiment of a sense block 500, such as sense block 350 in FIG. 2. An individual sense block 500 may be partitioned into a core portion, referred to as a sense module 580, and a common portion 590. In one embodiment, there is a separate sense module 580 for each bit line and one common portion 590 for a set of multiple sense modules 580. In one example, a sense block will include one common portion 590 and eight sense modules 580. Each of the sense modules in a group will communicate with the associated common portion via a data bus 572.

Sense module 580 comprises sense circuitry 570 that determines whether a conduction current in a connected bit line is above or below a predetermined threshold level. Sense module 580 also includes a bit line latch 582 that is used to set a voltage condition on the connected bit line. For example, a predetermined state latched in bit line latch 582 may result in the connected bit line being pulled to a state designating program inhibit voltage (e.g., 1.5-3 V).

Common portion 590 comprises a processor 592, a set of data latches 594, and an I/O Interface 596 coupled between the set of data latches 594 and data bus 520. Processor 592 performs computations. For example, processor 592 may determine the data stored in the sensed storage element and store the determined data in the set of data latches. Processor 592 may also move data between latches and perform operations on data in latches (e.g., performing logic operations such as Exclusive OR (XOR) operations. The set of data latches 594 may be used to store data bits determined by processor 592 during a read operation or to store data bits imported from the data bus 520 during a program operation. The imported data bits represent write data meant to be programmed into a memory array, such as memory array 501 in FIG. 5. I/O interface 596 provides an interface between data latches 594 and the data bus 520.

During a read operation or other storage element sensing operation, a state machine, such as state machine 512 in FIG. 5, controls the supply of different control gate voltages to the addressed storage elements. As it steps through the various predefined control gate voltages corresponding to the various memory states supported by the memory, the sense module 580 may trip at one of these voltages and an output will be provided from sense module 580 to processor 592 via bus 572. At that point, processor 592 determines the resultant memory state by consideration of the tripping event(s) of the sense module and the information about the applied control gate voltage from the state machine via input lines 593. It then computes a binary encoding for the memory state and stores the resultant data bits into data latches 594. In another embodiment of the core portion, bit line latch 582 serves both as a latch for latching the output of the sense module 580 and as a bit line latch as described above.

During a programming operation, the data to be programmed is stored in the set of data latches 594. The programming operation, under the control of the state machine 512, comprises a series of programming voltage pulses applied to the control gates of the addressed storage elements. Each program pulse is followed by a read back (or verify process) to determine if the storage element has been programmed to the desired memory state. Processor 592 monitors the read back memory state relative to the desired memory state. When the two are in agreement, the processor 592 sets the bit line latch 582 so as to cause the bit line to be pulled to a state designating program inhibit voltage. This inhibits the storage element coupled to the bit line from further programming even if program pulses appear on its control gate. In other embodiments, the processor initially loads the bit line latch 582 and the sense circuitry sets it to an inhibit value during the verify process.

Data latches 594 include a stack of data latches corresponding to the sense module. In one embodiment, there are three or more data latches per sense module 580. The data latches can be implemented as a shift register so that the parallel data stored therein is converted to serial data for data bus 520, and vice-versa. All the data latches corresponding to a read/write block can be linked together to form a block shift register so that a block of data can be input or output by serial transfer. In particular, the bank of read/write modules may be configured such that each of its set of data latches will shift data in to or out of the data bus in sequence as if they are part of a shift register for the entire read/write block.

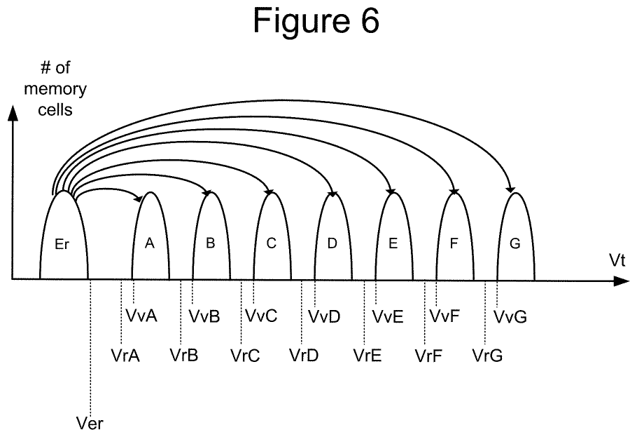

FIG. 6 illustrates an example of threshold voltage distributions for the memory array when each memory cell stores three bits of data. Other embodiments, however, may use other data capacities per memory cell (e.g., such as one, two, four, or five bits of data per memory cell). Storing more than one bit of data per memory cell using more than two data states is referred to as Multi-Level Cell (MLC), e.g., storing two bits per cell using four data states is an example of MLC. Storing one bit of data per memory cell using two data states is referred to a Single-Level Cell (SLC). Storing four bits of data per memory cell using sixteen data states is referred to as Quad-Level Cell (QLC). FIG. 6 shows eight threshold voltage distributions, corresponding to eight data states storing three bits of data (Three Level Cell, or TLC). The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits.

FIG. 6 shows seven verify reference voltages, VvA, VvB, VvC, VvD, VvE, VvF, and VvG. When programming memory cells to data state A, the system will test whether those memory cells have a threshold voltage greater than or equal to VvA. When programming memory cells to data state B, the system will test whether the memory cells have threshold voltages greater than or equal to VvB. When programming memory cells to data state C, the system will determine whether memory cells have their threshold voltage greater than or equal to VvC, and so on up to state G. FIG. 6 also shows Ver, which is a voltage level to test whether a memory cell has been properly erased.

FIG. 6 also shows seven read reference voltages, VrA, VrB, VrC, VrD, VrE, VrF, and VrG for reading data from memory cells. By testing whether the threshold voltage of a given memory cell is above or below the seven read reference voltages (e.g., performing sense operations using a sense block such as sense block 350), the system can determine what data state (e.g., Er, A, B, C, . . . ) a memory cell is in. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. While FIG. 6 shows all data states being programmed from the erased state together, in other examples, particularly with large numbers of data states, programming may be performed in multiple operations.

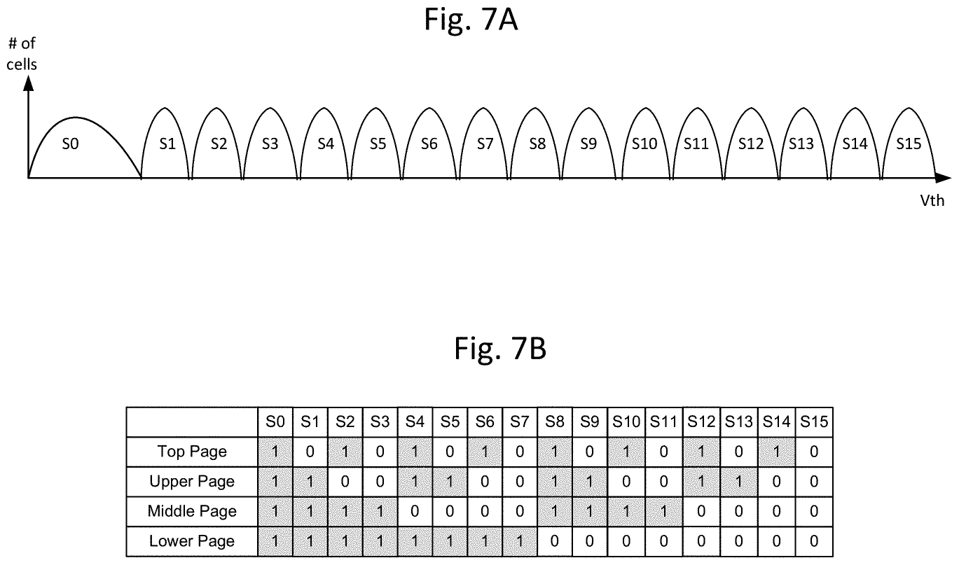

FIG. 7A shows an example of threshold voltages of non-volatile memory cells (e.g., non-volatile memory cells of memory structure 326) that are programmed into sixteen threshold voltage distributions (S0-S15) corresponding to sixteen data states. Programming and reading of non-volatile memory cells may be similar to the example of FIG. 6 (read and read-verify voltages are not shown in FIG. 7A). Using sixteen data states enables each non-volatile memory cell to store four bits of data and thus provides higher storage density than SLC, MLC, or TLC (e.g., FIG. 6) examples. Other numbers of data states may also be used.

FIG. 7B shows an example of an encoding scheme that may be used to map sixteen data states of FIG. 7A to four-bit values according to a binary code (other codes, including Gray codes, may also be used). Each data state S0-S15 corresponds to four bits, with each bit associated with a different logical page. Thus, a physical page of non-volatile memory cells may store four logical pages of data. In the example shown, each data state corresponds to one bit from each from a lower page, middle page, upper page, and top page as shown. Each logical page may be individually read using different read voltages so that it may be possible to access an individual logical page without reading all data states. For example, a lower page may be read using a single read voltage between S7 and S8. A middle page may be read using three read voltages: between S3 and S4, between S7 and S8, and between S11 and S12. An upper page may be read using seven read voltages: between S1 and S2, between S3 and S4, between S5 and S6, between S7 and S8, between S9 and S10, between S11 and S12, and between S13 and S14. A top page may be read using fifteen read voltages: between each of the sixteen data states S0-S15, e.g., between S0 and S1, between S1 and S2, between S2 and S3, and so on. Such a scheme may be referred to as a 1-3-7-15 scheme (referring to the numbers of read voltages for respective logical page read operations). Other schemes, such as 3-2-5-5 or 3-4-4-4 schemes, may also be used and the present technology is not limited to any particular encoding scheme.

When data is read from non-volatile memory cells, errors may occur in read data for a variety of reasons. In many cases, ECC may correct such errors. However, if the number of errors is high, it may exceed the capacity of ECC to correct the data (uncorrectable or UECC data). Even if the data is correctable, a large number of errors may take significant time and/or resources so that it generally desirable to have fewer “bad bits” in a given portion of data (e.g., a low bit error rate, or “BER”). When an encoding scheme such as shown in FIG. 7B is used, different logical pages may be affected by different phenomena, which may result in different error rates. For example, it can be seen that errors between data states S0 and S1 (e.g., some phenomenon causing overlap of corresponding threshold voltage distributions) may affect top page data but not affect lower page data while errors between data states S7 and S8 may affect all logical pages. Depending on the phenomena affecting particular data in a particular memory structure, different logical pages may be more or less affected. This may mean that one or more logical page has a high error rate while one or more other logical page has a low error rate. For example, in the example of FIG. 7B, the top page may have a higher error rate because it is affected by more phenomena than the other pages. Such concentrated error rates may result in UECC data and/or significant time for correction of data for some logical pages while other logical pages are easily corrected. ECC encoding schemes may be selected according to error rates so that such uneven distribution of error rates may require a higher ECC encoding rate (more redundancy) than would be required if there was a more even distribution. Thus, a more even distribution of errors across portions of data of data may be preferable to having errors concentrated in particular portions of data.

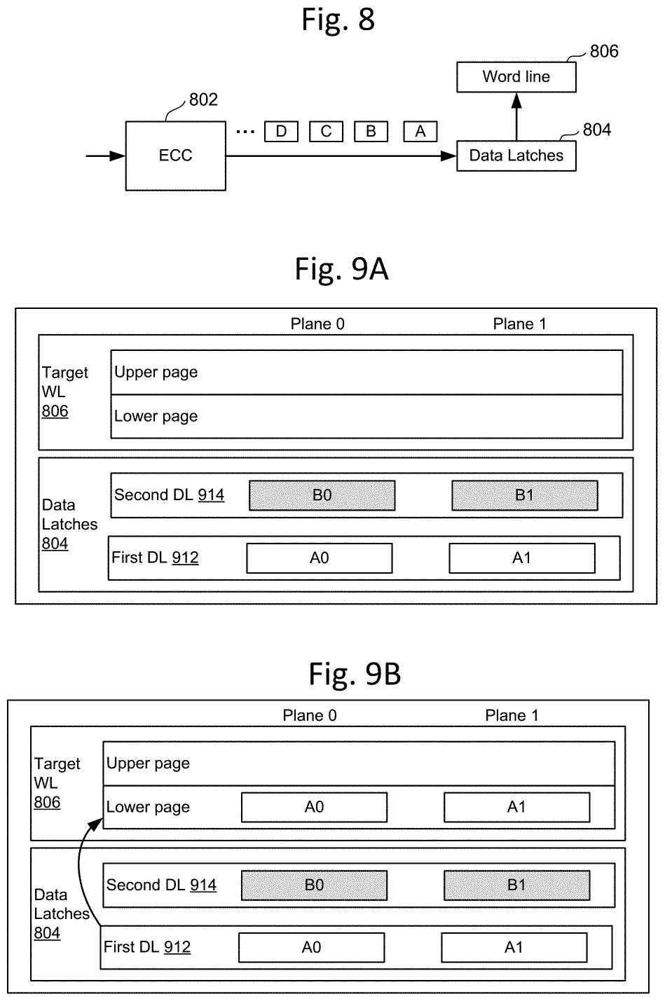

FIG. 8 shows an example of operation of a storage system that includes an ECC engine 802 (e.g., ECC engine 226, 256 or other suitable ECC encoder/decoder circuit), which encodes data according to a suitable encoding scheme that allows detection and correction of errors when data is later read from non-volatile memory cells. ECC engine 802 encodes data to generate encoded portions of data A, B, C, D . . . as illustrated and sends the encoded portions of data for storage in non-volatile memory cells (e.g., in memory structure 326). For example, encoded portions A-B may be sent for storage in MLC non-volatile memory cells (two bits per cell) along a target word line 806 in a memory structure (e.g., memory structure 326), encoded portions A-D may be sent for storage in QLC non-volatile memory cells (four bits per cell) along target word line 806, or some other number of portions may be stored depending on configuration. Between ECC engine 802 and target word line 806, data may be latched in data latches 804 (e.g., data latches 594) for programming into target word line 806. The number of rows of such latches may depend on the number of logical pages to be stored together (e.g., depends on the number of bits per non-volatile memory cell).

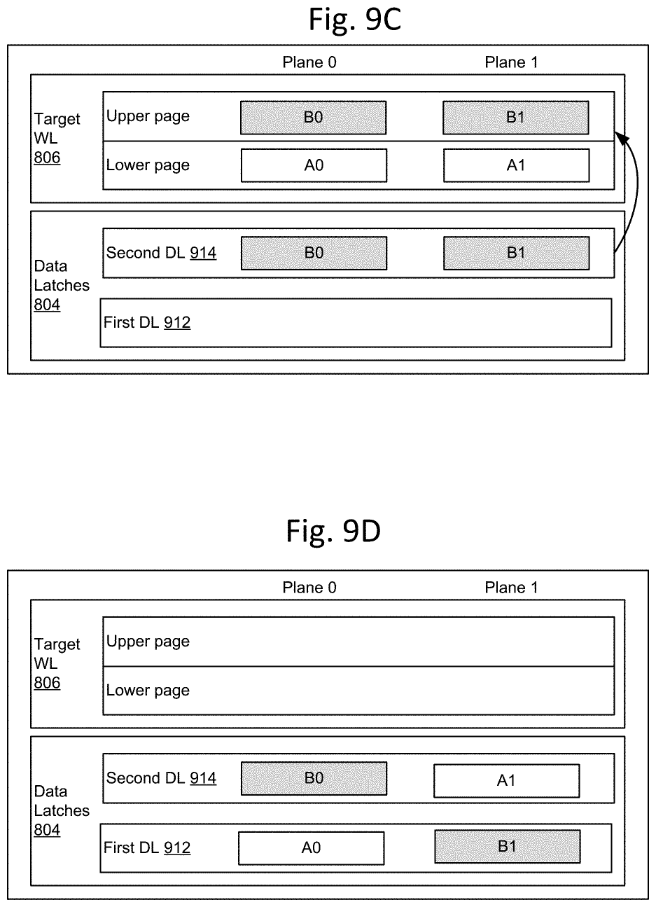

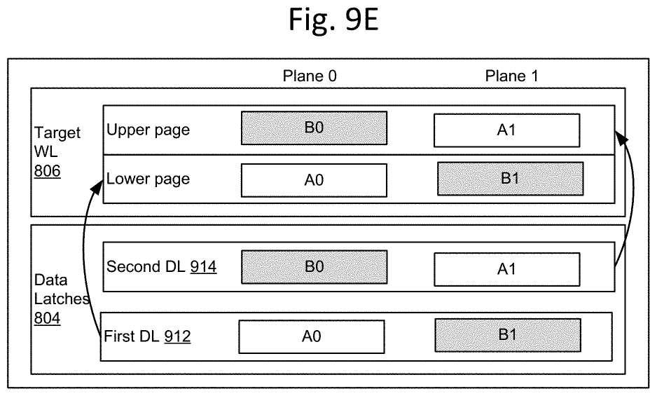

FIG. 9A shows an example scheme for programming target word line 806 in which non-volatile memory cells of target word line 806 are configured to hold two bits each and non-volatile memory cells of target word line 806 together store two logical pages (lower page and upper page). Target word line 806 extends across two planes (Plane 0 and Plane 1) in this example. Data latches 804 include a first row of data latches (DL) 912 and a second row of data latches DL 914, each having capacity for one logical page of data. As shown in FIG. 9A, first DL 912 may store encoded portion A (shown as two parts, A0 and A1 corresponding to plane 0 and plane 1 respectively) and second DL 914 may store encoded portion B (shown as two parts, B0 and B1 corresponding to plane 0 and plane 1 respectively).

Subsequent to latching encoded data portions A-B into first DL 912 and second DL 914 as shown, data may be programmed as lower and upper page data in non-volatile memory cells along target WL 806. FIG. 9B illustrates a first programming operation to program encoded portion A (A0-A1) as lower logical page data along target WL 806. FIG. 9C illustrates a second programming operation to program encoded portion B (B0-B1) as upper logical page data along target WL 806. Such a programming scheme may result in unequal error rates between encoded portion A (A0-A1) and encoded portion B (B0-B1) because they are stored as lower and upper logical pages respectively and are therefore subject to different disturbance phenomena. Unequal error rates may occur even where programming of logical pages is combined (e.g., the steps of FIGS. 9B and 9C are performed together in a “WL program” operation instead of two “page program” operations shown). For example, if upper page error rates are high then encoded portion B may have higher error rate than encoded portion A, which may be undesirable.

FIG. 9D shows an alternative arrangement of encoded portion A (parts A0-A1) and encoded portion B (parts B0 and B1) in data latches 804. As shown in FIG. 9D, part A0 of encoded portion A and part B1 of encoded portion B are located in first DL 912 while another part B0 of encoded portion B and another part A1 of encoded portion A are located in second DL 914. Thus, each encoded portion A, B, is distributed across two rows of data latches (first DL 912 and second DL 914) and each row contain parts of both portions of data.

Subsequent to arranging data as illustrated in FIG. 9D, data may be programmed to target WL 806 as illustrated in FIG. 9E so that distributed encoded portions are arranged as shown. Data from first DL 912 is programmed as lower page data in non-volatile memory cells of target word line 806 and data from second DL 914 is programmed as upper page data in non-volatile memory cells of target word line 806 (this may be done in two operations as illustrated in FIGS. 9B-C). The result of this programming is that parts A0 and B1 of data encoded portions A and B respectively are stored as lower page data while parts B0 and A1 of encoded portions B and A respectively are stored as upper page data in non-volatile memory cells along target word line 806. In this case, if there are different error rates for different logical pages (e.g., upper and lower logical pages have different error rates when data is read), because the data portions are distributed across the logical pages, each encoded portion A, B, has an error rate that is an average of the upper and lower page error rates (e.g., combined error rate for parts A0 and A1 may be between error rates of the upper and lower logical pages). Thus, both portions may have similar error rates that may be at some intermediate level. This may reduce the chances of UECC data and may reduce the number of portions of data requiring excessive time and/or resources for decoding. Lower error rates may allow a lower encoding rate (less redundant data) so that more user data may be stored in a given memory structure.

Aspects of the present technology may be applied in memory structures configured to store different numbers of bits per cell (different numbers of logical pages per physical page) according to different encoding schemes and may also be applied across any number of planes.

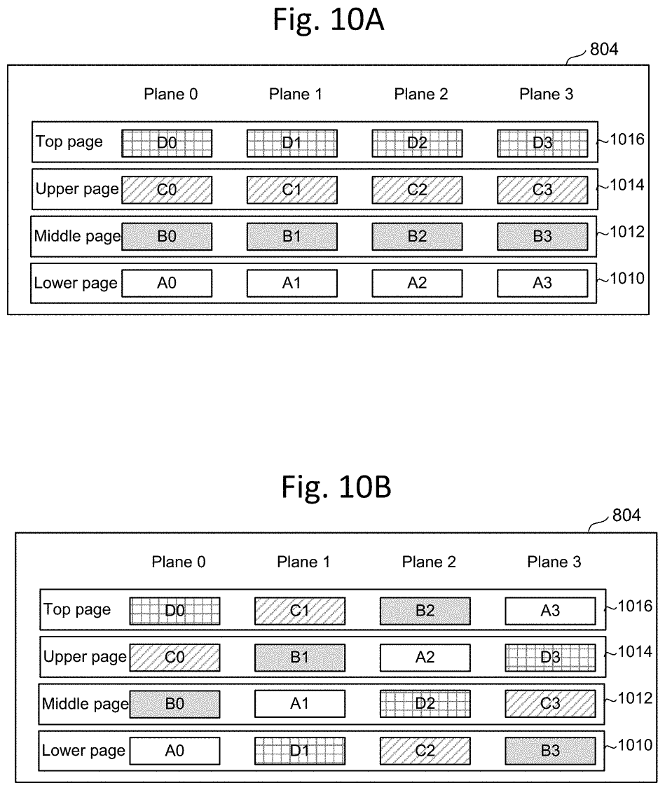

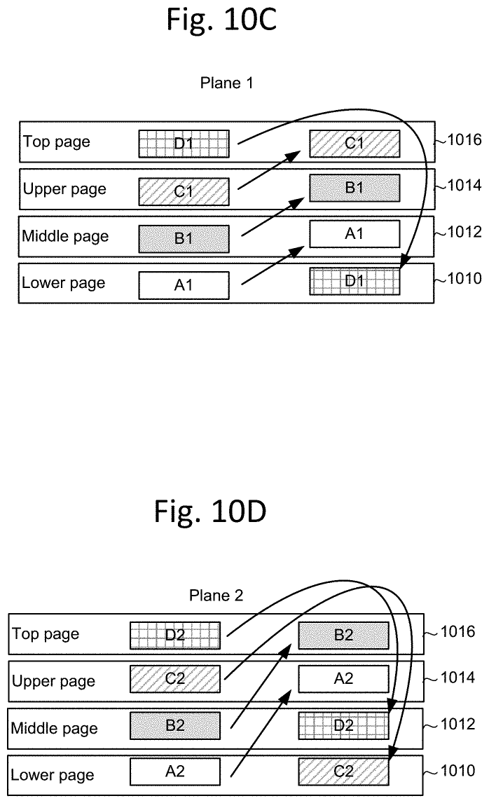

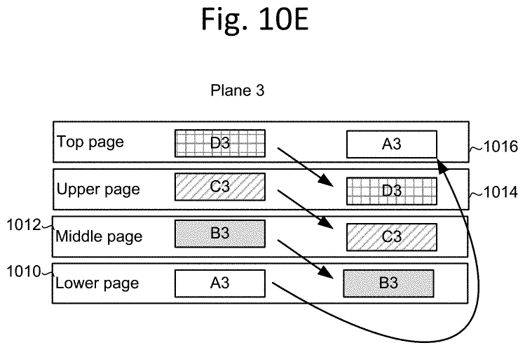

FIGS. 10A-E illustrate examples implemented in data latches 804 for non-volatile memory cells configured for QLC operation with four planes operated in parallel (e.g., non-volatile memory cells of target word line 806 configured as QLC cells). Encoded portions A-D of FIG. 10A extend across four planes (plane 0-plane 3) in this example so that each data portion includes four parts (e.g., data portion A includes parts A0, A1, A2, and A3). Encoded portions A-D may be individually encoded by ECC engine 802 so that each encoded portion represents a minimum unit for ECC decoding. For example, each encoded portion A-D may be an ECC codeword or may a combination of ECC codewords that are decoded together. Individual parts (e.g., A0, A1, A2, A3) may not be individually ECC decoded in this example. Thus, an encoded portion may be considered a minimum ECC unit in the example shown.

FIG. 10A shows each data portion latched in a corresponding row of data latches (similar to the example of FIG. 9A), with each row of data latches corresponding to a different logical page. Data portion A (parts A0-A3) is in lower page data latches 1010, data portion B (parts B0-B3) is located in middle page data latches 1012, data portion C (parts C0-C3) is located in upper page data latches 1014, and data portion D (parts D0-D3) is located in top page data latches 1016 (assignment of latches to particular logical pages may be changeable and there may not be a fixed correspondence between logical pages and latches). As discussed with respect to the example above, such an arrangement may result in higher error rates for some portions of data than others due to the logical page assignment.

FIG. 10B illustrates an example of encoded portions A-D arranged in rows of data latches 1010, 1012, 1014, 1016, such that each encoded portion is distributed across four rows of data latches. When data is subsequently programmed as lower, middle, upper, and top page data along a target word line, each encoded portion of data is distributed across logical pages so that differences in error rates between logical pages are averaged within a given encoded portion and differences in error rates between encoded portions may be relatively small. Arranging encoded portions of data so that they are distributed across two or more rows of data latches (e.g., as shown in FIGS. 9D and 10B) may be achieved in various ways and the present technology is not limited to any particular manner of arranging, or to the examples illustrated.

FIGS. 10C-E illustrate an example in which data is rearranged, or scrambled, within data latches 804 from the arrangement shown in FIG. 10A (with each encoded portion of data in a corresponding row of data latches, e.g., encoded portion A in data latches 1010, encoded portion B in data latches 1012, encoded portion C in data latches 1014, and encoded portion D in data latches 1016) to an arrangement in which each encoded portion is distributed across multiple rows of data latches. In the example shown, scrambling is performed on a plane-by-plane basis, with different scrambling applied to different planes. Because the arrangement of data remains the same in plane 0 in FIGS. 10A and 10B, no scrambling is performed in plane 0 in this example (in other examples, all planes may be scrambled, or one or more different planes may be unchanged).

FIG. 10C shows rotation of parts of latched data in plane 1 from the arrangement of FIG. 10A to the arrangement of FIG. 10B. It can be seen that parts are rotated by one row of latches (e.g., part A1 from lower page latches 1010 to middle page latches 1012, part B1 from middle page latches 1012 to upper page latches 1014, part C1 from upper page latches 1014 to top page latches 1016, and part D1 from top page latches 1016 to lower page latches 1010) in plane 1.

FIG. 10D shows rotation of parts of latched data in plane 2 from the arrangement of FIG. 10A to the arrangement of FIG. 10B. It can be seen that parts are rotated by two rows of latches (e.g., part A2 from lower page latches 1010 to upper page latches 1014, part B2 from middle page latches 1012 to top page latches 1016, part C2 from upper page latches 1014 to lower page latches 1010, and part D2 from top page latches 1016 to middle page latches 1012) in plane 2.

FIG. 10E shows rotation of parts of latched data in plane 3 from the arrangement of FIG. 10A to the arrangement of FIG. 10B. It can be seen that parts are rotated by three rows of latches, which is equivalent to rotating back by one row of latches (e.g., part A3 from lower page latches 1010 to top page latches 1016, part B3 from middle page latches 1012 to lower page latches 1010, part C3 from upper page latches 1014 to middle page latches 1012, and part D3 from top page latches 1016 to upper page latches 1014) in plane 3.

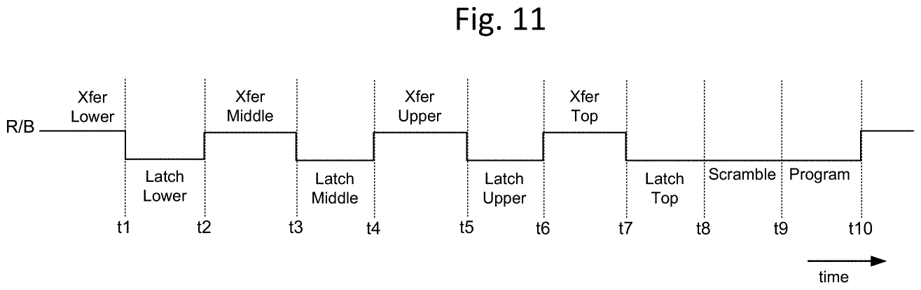

FIG. 11 shows a timing diagram for a programming operation that scrambles data in latches (e.g., in data latches 804 is illustrated in examples above). A ready/busy (R/B) signal is shown along with steps occurring during the operation. Prior to time t1, lower page data is transferred (e.g., from a memory controller and/or host to on-chip latches or buffers provided for transfer of data) and between t1 and t2 the lower page data is latched (e.g., transfer of encoded portion A and subsequent latching into lower page latches 1010). Between time t2 and t3, middle page data is transferred and is subsequently latched between t3 and t4 (e.g., transfer of encoded portion B and subsequent latching into middle page latches 1012). Between time t4 and t5, upper page data is transferred and is subsequently latched between t5 and t6 (e.g., transfer of encoded portion C and subsequent latching into upper page latches 1014). Between time t6 and t7, top page data is transferred and is subsequently latched between t7 and t8 (e.g., transfer of encoded portion D and subsequent latching into top page latches 1016). Thus, at time t8, data may be arranged as illustrated in FIG. 10A. Subsequently, between t8 and t9, data is scrambled as previously discussed (e.g., to achieve the arrangement of FIG. 10B using plane-by-plane rotation as illustrated in FIGS. 10C-10E). The scrambled data is then programmed between t9 and t10. Because the data was scrambled in the latches, each portion of data is distributed across multiple logical pages of the target word line. In general, the time for scrambling (t8 to t9) represents a small part of the programming operation and may have little impact on overall programming time.

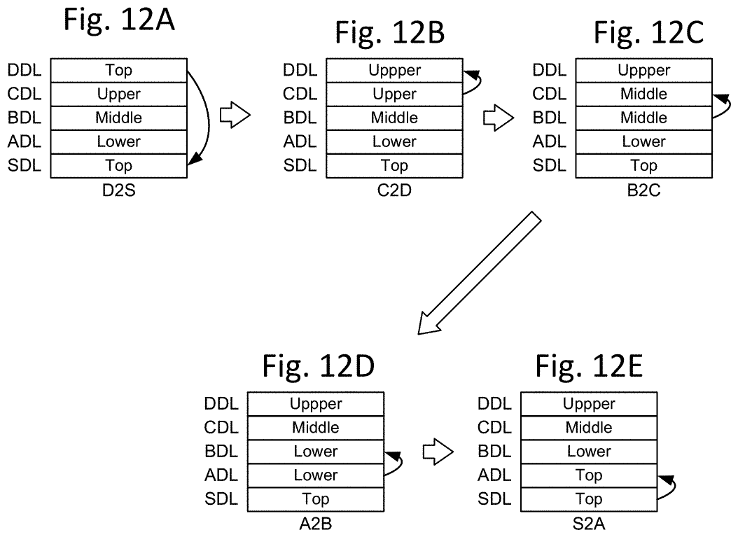

Scrambling of data in rows of data latches may be performed in many different ways depending on the number and configuration of latches available and the desired result. Rotating data by different amounts in different latches as illustrated in FIGS. 10C-E provides one example. An example implementation of rotation by plane in a four plane structure using five rows of data latches is illustrated in FIGS. 12A-14E. Other scrambling techniques (using rotation or otherwise) may also be used.

FIGS. 12A-E illustrate an implementation of rotation by one row of latches (e.g., as previously illustrated in FIG. 10C) using five rows of data latches (DLs): SDL, ADL, BDL, CDL, and DDL. For example, ADL may be assigned as lower page latches (e.g., lower page latches 1010), BDL may be assigned as middle page latches (e.g., middle page latches 1012), CDL may be assigned as upper page latches (e.g., upper page latches 1014), CDL may be assigned as top page latches (e.g., top page latches 1016), and SDL may be used as an additional row of latches to facilitate rotation of data.

FIG. 12A shows top page data copied from DDL to SDL. This is indicated as “D2S” in FIG. 12A, with similar notation used in other figures to indicate the origin latches and destination latches linked by “2” (e.g., “D2S” indicates copying from D to S). FIG. 12B shows subsequent copying of upper page data from CDL to DDL (“C2D”). FIG. 12C shows copying of middle page data from BDL to CDL (“B2C”). FIG. 12D shows copying of lower page data from ADL to BDL (“A2B”). And FIG. 12E shows copying of top page data from SDL to ADL (“S2A”). The result of the series of steps of FIGS. 12A-E is rotation of data by one latch.

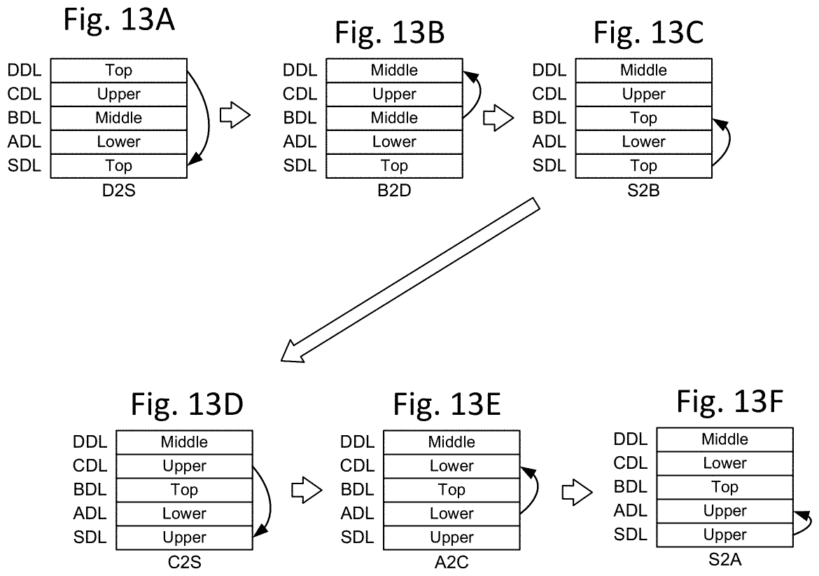

FIGS. 13A-F illustrate an implementation of rotation by two rows of latches as previously illustrated in FIG. 10D using rows SDL, ADL, BDL, CDL, and DDL. Latches may be assigned to lower, middle, upper, and top pages as previously described.

FIG. 13A shows top page data copied from DDL to SDL (“D2S). FIG. 13B shows copying of middle page data from BDL to DDL (“B2D”). FIG. 13C shows copying of top page data from SDL to BDL (“S2B”). FIG. 13D shows copying of upper page data from CDL to SDL (“C2S”). FIG. 13E shows copying of lower page data from ADL to CDL (“A2C”). And FIG. 13F shows copying of upper page data from SDL to ADL (“S2A”). The result of the series of steps of FIGS. 13A-F is rotation of data by two latches.

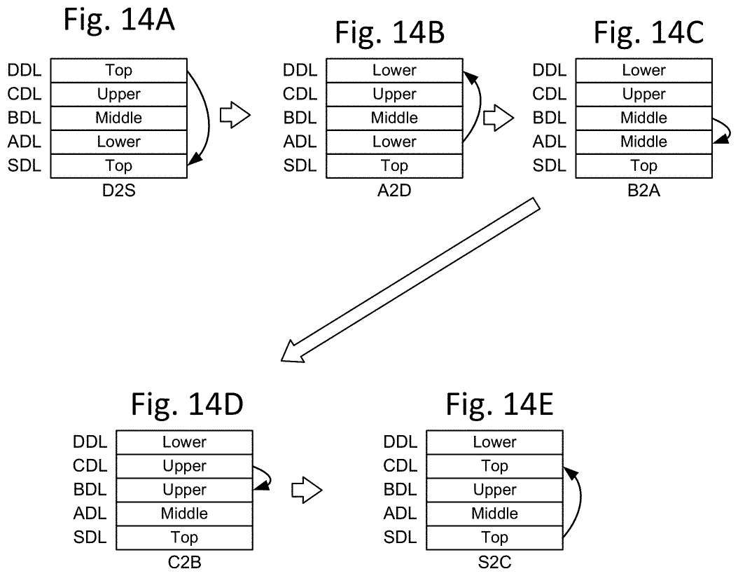

FIGS. 14A-E illustrate an implementation of rotation by three rows of latches (negative rotation by one row of latches) as previously illustrated in FIG. 10E using rows SDL, ADL, BDL, CDL, and DDL. Latches may be assigned to lower, middle, upper, and top pages as previously described.

FIG. 14A shows top page data copied from DDL to SDL (“D2S”). FIG. 14B shows copying of lower page data from ADL to DDL (“A2D”). FIG. 14C shows copying of middle page data from BDL to ADL (“B2A”). FIG. 14D shows copying of upper page data from CDL to BDL (“C2B”). And FIG. 14E shows copying top page data from SDL to CDL (“S2C”). The result of the series of steps of FIGS. 14A-E is rotation of data by three latches.

Scrambling of data that is already loaded in latches on a non-volatile memory die (“on-chip” scrambling) may be performed sequentially, one plane at a time, or may be performed for multiple planes in parallel (e.g., scrambling any planes that are to be scrambled at substantially the same time).

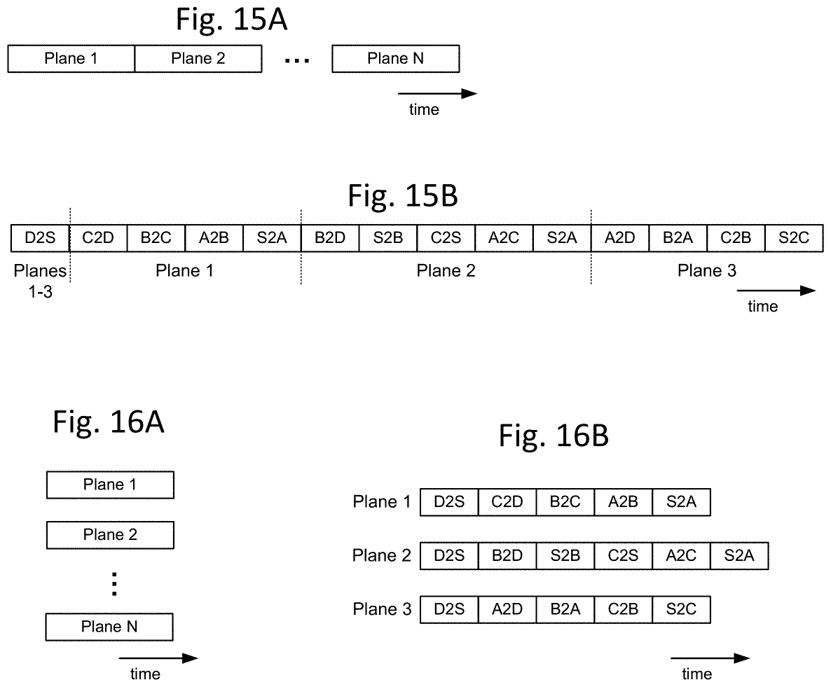

FIG. 15A illustrates an example of sequential scrambling of latched data of different planes in an N-plane structure, which may be applied to data in data latches (e.g., data latches 804). Data of plane 1 is scrambled (e.g., rotated) first, followed by plane 2, and so on until data of plane N is scrambled. FIG. 15A may alternatively illustrate sequential scrambling of N planes of an N+1 plane structure (e.g., plane 0 is not scrambled as in previous examples) or N planes of an N+x plane structure where x represents a number of planes that are not rotated (which can be any number depending on the memory structure and scrambling requirements).

FIG. 15B illustrates an example implementation of sequential scrambling (e.g., of FIG. 15A with N=3) using plane-by-plane rotation of data (e.g., rotation as previously described with respect to FIGS. 12A-14E). In a first step, data in DDL of planes 1-3 is copied to SDL (D2S) in parallel (this step is common to planes 1-3 as shown in FIGS. 12A, 13A, 14A). Subsequently, rotation of data is performed in plane 1 according to the steps illustrated in FIGS. 12B-E: C2D, B2C, A2B, and S2A. Scrambling of plane 1 data is followed by scrambling of plane 2 data according to the steps illustrated in FIGS. 13B-F: B2D, S2B, C2S, A2C, and S2A. Scrambling of plane 2 data is followed by scrambling of plane 3 data according to the steps illustrated in FIGS. 14B-E: A2D, B2A, C2B, and S2C. No scrambling of plane 0 data is performed in this example so that scrambling may be considered complete after plane 3 data is scrambled.

In an alternative to the sequential scrambling of FIGS. 15A-B, FIGS. 16A-B illustrate examples of parallel scrambling. FIG. 16A shows parallel scrambling of data of planes 1 to N (e.g., all planes of an N-plane structure or N of N+x planes where x may be any number).

FIG. 16B shows parallel scrambling using plane-by-plane rotation of data of planes 1-3 (e.g., as previously described with respect to FIGS. 12A-14E). Plane 1 data is rotated by one latch as illustrated in FIGS. 12A-E using steps: D2S, C2D, B2C, A2B, and S2A. In parallel with rotating data of plane 1, data of plane 2 is rotated by two latches as illustrated in FIGS. 13A-F using steps: D2S, B2D, S2B, C2S, A2C, and S2A. In parallel with rotating data of planes 1 and 2, data of plane 3 is rotated by three latches as illustrated in FIGS. 14A-E using steps: D2S, A2D, B2A, C2B, and S2C. Data of plane 0 is not rotated in this example. A handshaking protocol may be implemented for end detection to determine when scrambling is complete in planes 1-3.

It can be seen that parallel scrambling may be faster than sequential scrambling (e.g., plane-by-plane rotation in series as shown in FIG. 15B may take over 20 microseconds while rotation in parallel as shown in FIG. 16B may take less than 10 microseconds in an example.

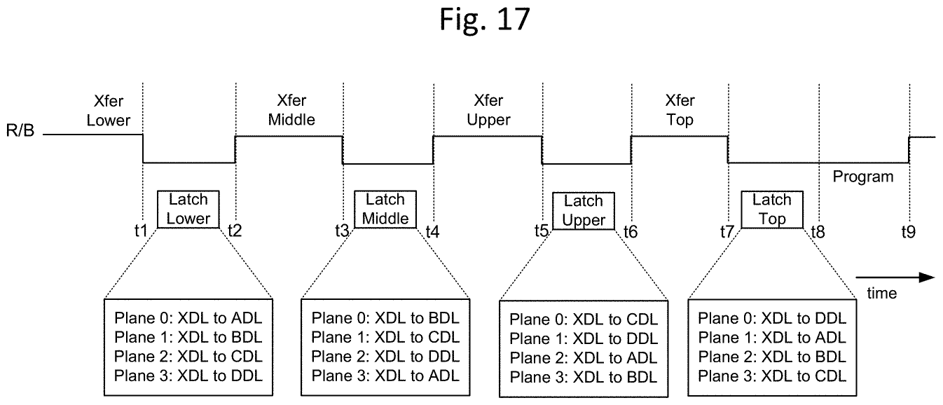

In an alternative to scrambling data after the data is loaded in data latches for programming (e.g., in data latches 804), data may be arranged in a desired arrangement as it is received (e.g., without initially latching the data in another arrangement). FIG. 17 shows a timing diagram of a scheme that arranges data as it is received so that subsequent scrambling in data latches is not necessary (e.g., no separate scrambling step is required). The timing diagram of FIG. 17 may be compared with the timing diagram of FIG. 11, which includes scrambling after data is in data latches.

Lower page data is transferred (e.g., from a memory controller or host) into a transfer latch (XDL) prior to time t1 and is then latched for programming from t1 to t2. In contrast to FIG. 11, FIG. 17 shows this data (e.g., encoded portion A) latched differently in different planes. Plane 0 data is copied from XDL to ADL. Plane 1 data is copied from XDL to BDL. Plane 2 data is copied from XDL to CDL. And plane 3 data is copied from XDL to DDL. Subsequently, middle page data (e.g., encoded portion B) is transferred between t2 and t3 and is then latched from t3 to t4, with data of different planes latched differently. Plane 0 data is copied from XDL to BDL. Plane 1 data is copied from XDL to CDL. Plane 2 data is copied from XDL to DDL. And plane 3 data is copied from XDL to ADL. Subsequently, upper page data (e.g., encoded portion C) is transferred between t4 and t5 and is then latched from t5 to t6, with data of different planes latched differently. Plane 0 data is copied from XDL to CDL. Plane 1 data is copied from XDL to DDL. Plane 2 data is copied from XDL to ADL. And plane 3 data is copied from XDL to BDL. Subsequently, top page data (e.g., encoded portion D) is transferred between t6 and t7 and is then latched from t7 to t8, with data of different planes latched differently. Plane 0 data is copied from XDL to DDL. Plane 1 data is copied from XDL to ADL. Plane 2 data is copied from XDL to BDL. And plane 3 data is copied from XDL to CDL. This results in data being arranged in latches as shown in FIG. 10B. Programming then occurs between t8 and t9 (e.g., immediately after latching of top page data, without a separate scrambling operation). For example, data in ADL may be programmed as lower page data, data in BDL as middle page data, data in CDL as upper page data, and data in DDL as top page data so that each portion of data is distributed across lower, middle, upper, and top pages. Because no separate scrambling operation is required in this example, overall programming time may not be affected by arranging data as desired (e.g., as shown in FIG. 10B). In some cases, one or more data latches ADL, BDL, CDL, DDL may be in use when data is transferred (e.g., completing prior program operation) so that arranging data in this way as it is received may not be possible and scrambling may be performed after all data for the word line is latched.

Subsequent to storing data, the data may be accessed (e.g., read in response to a read command). In order to read the correct data, the correct location must be accessed. When data to be accessed was scrambled when it was programmed, some address translation may be provided to ensure that the correct data is obtained. For example, when a read command specifies data of a top page and the top page data was distributed across lower, middle, upper, and top logical pages in a scrambling scheme, parts of the data in lower, middle, and upper logical pages may be accessed in addition to a part in the top logical page. In some cases, a memory controller may be configured to correct addresses to accommodate a scrambling scheme (e.g., instead of sending a read command specifying top page data, sending a read command that specifies particular logical page+plane combinations such as top page of plane 0, lower page of plane 1, middle page of plane 2, and upper page of plane 3). In other examples, translation may be performed by control circuits (e.g., on a memory die) separate from the memory controller (e.g., the scrambling and descrambling may occur without memory controller involvement.

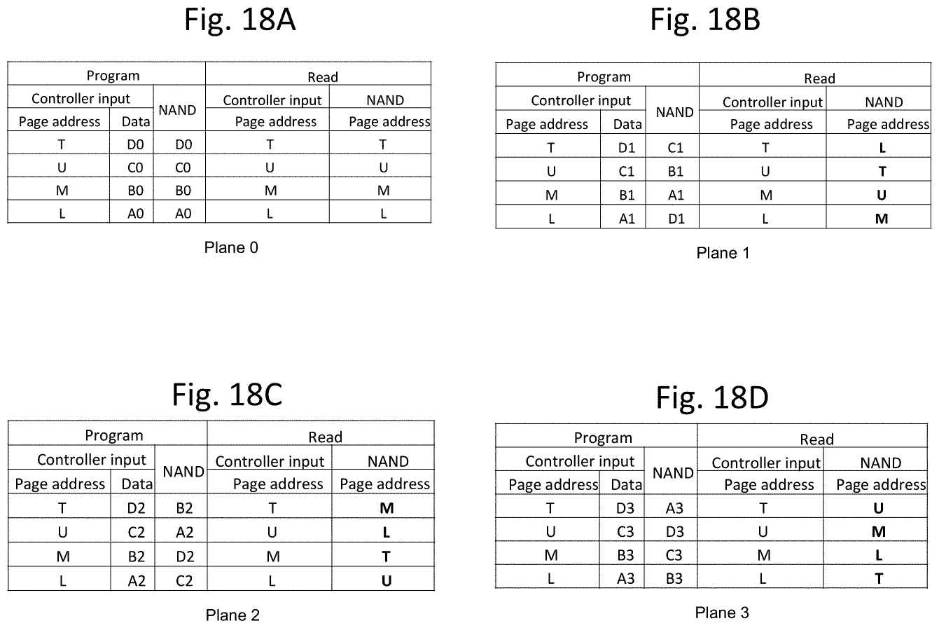

FIGS. 18A-D illustrate an example of how read commands from a memory controller may be handled by control circuits (in a NAND memory die or integrated memory assembly) so that the correct data is accessed when it is scrambled (e.g., as illustrated in FIG. 10B). Each of FIGS. 18A-D show tables indicating mapping of page addresses from a controller to locations in NAND during programming on the left (e.g., scrambling according to examples above) and mapping of page addresses to NAND locations for read commands on the right.

FIG. 18A shows an example of address translation for plane 0. The controller input for program (e.g., write command) may include data parts A0, B0, C0, and D0 for page addresses lower (L), middle (M), upper (U), and top (T). Plane 0 is not scrambled in the above examples. In a read operation (e.g., in response to a read command), when the controller specifies page addresses L, M, U, and T, control circuits accesses data in NAND in lower, middle, upper, and top pages respectively (no change).

FIG. 18B shows an example of address translation for plane 1. The controller input (e.g., write command) may include data parts A1, B1, C1, and D1 for lower, middle, upper, and top pages respectively. These are scrambled (rotated in this example) in data latches (e.g., as shown in FIG. 10C) and written in NAND as illustrated with A1 in the middle page, B1 in the upper page, C1 in the top page, and D1 in the lower page. Subsequently, in a read operation (e.g., in response to a read command), when the controller specifies page addresses L, M, U, and T, control circuits access data in NAND in M, U, T, and L pages respectively (e.g., reading data A1 in a middle page read operation, not a lower page read operation, in response to a read command directed to lower page data of plane 1).

FIG. 18C shows an example of address translation for plane 2. The controller input (e.g., write command) includes data parts A2, B2, C2, and D2 for L, M, U, and T pages respectively. These are scrambled (rotated in this example) in data latches (e.g., as shown in FIG. 10D) and written in NAND as illustrated with A2 in the upper page, B2 in the top page, C2 in the lower page, and D2 in the middle page. Subsequently, in a read operation (e.g., in response to a read command), when the memory controller specifies page addresses L, M, U, and T, control circuits access data in NAND in U, T, L, and M pages respectively (e.g., reading data A2 in an upper page read operation, not a lower page read operation, in response to a read command directed to lower page data of plane 2).

FIG. 18D shows an example of address translation for plane 3. The controller input (e.g., write command) includes data parts A3, B3, C3, and D3 for L, M, U, and T pages respectively. These are scrambled (rotated in this example) in data latches (e.g., as shown in FIG. 10E) and written in NAND as illustrated with A3 in the top page, B3 in the lower page, C3 in the middle page, and D3 in the upper page. Subsequently, in a read operation (e.g., in response to a read command), when the memory controller specifies page addresses L, M, U, and T, control circuits access data in NAND in T, L, M, and U pages respectively (e.g., reading data A3 in a top page read operation, not a lower page read operation, in response to a read command directed to lower page data of plane 3).

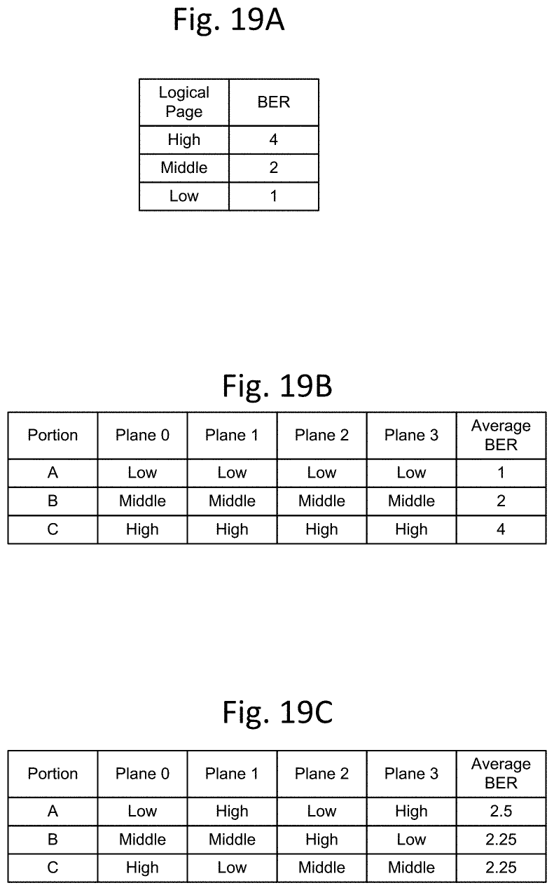

While the examples above show an even number of logical pages (two or four) per word line, the present technology is not limited to such examples and may be implemented in non-volatile memory cells that store any number (including odd numbers) of logical pages in non-volatile memory cells along a word line. FIGS. 19A-C illustrate an example implementation in TLC non-volatile memory cells in which non-volatile memory cells along a word line are configured to store three logical pages of data: low, middle, and high pages.

FIG. 19A shows different example error rates (BER) for low, middle, and high pages as 1, 2, and 4 respectively. Thus, errors are concentrated in data stored in higher pages.

FIG. 19B shows a first arrangement in which encoded portions A, B, C are each stored in corresponding rows of data latches and programmed to corresponding logical pages. Data portion A is programmed as low page data in planes 0-3 and therefore has an average BER of 1. Data portion B is programmed as middle page data in planes 0-3 and therefore has an average BER of 2. Data portion C is programmed as high page data in planes 0-3 and therefore has an average BER of 4.

FIG. 19C shows an alternative arrangement in which each encoded portion is distributed across at least two logical pages to even out error rates. Encoded portion A is programmed as low page data in planes 0 and 2 and as high page data in planes 1 and 3. This gives an average BER for encoded portion A of 2.5. Encoded portion B is programmed as middle page data in planes 0-1, high page data in plane 2, and low page data in plane 3. This gives an average BER for encoded portion B of 2.25. Encoded portion C is programmed as high page data in plane 0, low page data in plane 1, and middle page data in planes 2-3. This gives an average BER for encoded portion C of 2.25. Because the structure has four planes and three logical pages, there remains some difference between error rates. However, it can be seen that the highest error rate is reduced from 4 to 2.5 so that UECC is less likely, and a lower encoding rate may be used.

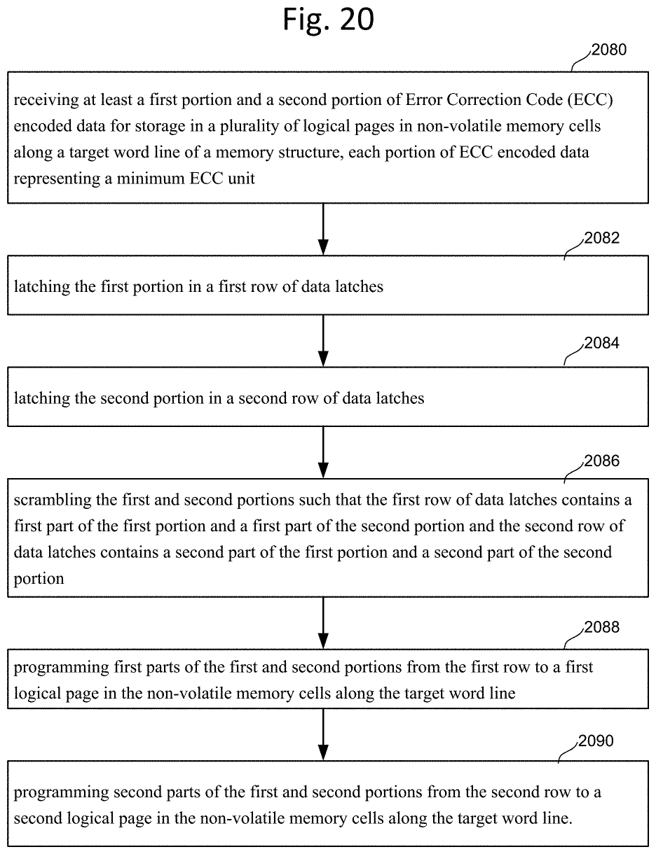

FIG. 20 illustrates an example of a method that may be implemented in a memory system (e.g., memory system 100) and may result in more even distribution of errors. The method includes receiving at least a first portion and a second portion of Error Correction Code (ECC) encoded data for storage in a plurality of logical pages in non-volatile memory cells along a target word line of a memory structure, each portion of ECC encoded data representing a minimum ECC unit 2080 (e.g., two or more of portions A, B, C, D in examples above), latching the first portion in a first row of data latches 2082 and latching the second portion in a second row of data latches 2084. The method further includes scrambling the first and second portions such that the first row of data latches contains a first part of the first portion and a first part of the second portion and the second row of data latches contains a second part of the first portion and a second part of the second portion 2086 (e.g., as shown in FIG. 9D or 10B), programming first parts of the first and second portions from the first row to a first logical page in the non-volatile memory cells along the target word line 2088, and programming second parts of the first and second portions from the second row to a second logical page in the non-volatile memory cells along the target word line 2090 (e.g., as shown in FIG. 9E)

While specific examples are described above, including specific logical pages, planes, latches, etc., it will be understood that aspects of the present technology are not limited to such examples and may be extended to a wide variety of non-volatile memories using a variety of configurations. Aspects of the present technology may be implemented using any suitable hardware. For example, control circuits 310 and/or read/write circuits 328, or circuits of control die 311 may perform steps described above and may be considered means for scrambling a plurality of encoded portions of data prior to programming the plurality of encoded portions of data in the plurality of logical pages in the plurality of non-volatile memory cells such that each encoded portion is distributed among the plurality of logical pages.

An example of an apparatus includes one or more control circuits configured to connect to a plurality of non-volatile memory cells arranged along word lines. The one or more control circuits are configured to: receive a plurality of encoded portions of data to be programmed in non-volatile memory cells of a target word line, each encoded portion of data encoded according to an Error Correction Code (ECC) encoding scheme, arrange the plurality of encoded portions of data in a plurality of rows of data latches corresponding to a plurality of logical pages such that each encoded portion of data is distributed across two or more rows of data latches, and program the distributed encoded portions of data from the plurality of rows of data latches into non-volatile memory cells along a target word line.

The one or more control circuits may be further configured to divide each encoded portion of data into a plurality of parts of equal size, each part arranged in a different row of latches. Non-volatile memory cells of the target word line may be configured to store n logical pages of data, the plurality of encoded portions of data may consist of n encoded portions each equal in size to one logical page, and the one or more control circuits may be further configured to program part of each encoded portion of data in each logical page of non-volatile memory cells of the target word line. The one or more control circuits may be further configured to distribute each encoded portion of data across the plurality rows of data latches as each encoded portion of data is received. The one or more control circuits may be further configured to initially arrange each of the plurality of encoded portions of data in a respective row of data latches and subsequently scramble the plurality of encoded portions of data such that each encoded portion of data is distributed across the plurality of rows of data latches. The one or more control circuits may be further configured to scramble the plurality of encoded portions of data by rotating parts of the plurality of encoded portions of data between rows of data latches. The one or more control circuits may be further configured to rotate parts of the plurality of encoded portions for two or more planes in series. The one or more control circuits may be further configured to rotate parts of the plurality of encoded portions for two or more planes in parallel. The one or more control circuits, the plurality of rows of data latches and the plurality of non-volatile memory cells may be located in a memory die. The one or more control circuits may be further configured to receive a read command directed to an encoded portion of data in the non-volatile memory cells along the target word line and read of the encoded portion by reading at least a first part of the encoded portion in a first logical page using a first set of read voltages and a second part of the encoded portion in a second logical page using a second set of read voltages.

An example of a method includes receiving at least a first portion and a second portion of Error Correction Code (ECC) encoded data for storage in a plurality of logical pages in non-volatile memory cells along a target word line of a memory structure, each portion of ECC encoded data representing a minimum ECC unit, latching the first portion in a first row of data latches, and latching the second portion in a second row of data latches. The method further includes scrambling the first and second portions such that the first row of data latches contains a first part of the first portion and a first part of the second portion and the second row of data latches contains a second part of the first portion and a second part of the second portion, programming first parts of the first and second portions from the first row to a first logical page in the non-volatile memory cells along the target word line; and programming second parts of the first and second portions from the second row to a second logical page in the non-volatile memory cells along the target word line.

The method may further include receiving a third portion and a fourth portion of ECC encoded data for storage in the plurality of logical pages; and scrambling the third and fourth portions with the first and second portions such that the first row of data latches additionally contains a first part of the third portion and a first part of the fourth portion, the second row additionally contains a second part of the third portion and a second part of the fourth portion, a third row of data latches contains a third part of each of the first, second, third, and fourth portions, and a fourth row of data latches contains a fourth part of each of the first, second, third, and fourth portions. The method may further include programming the first parts of the third and fourth portions with the first parts of the first and second portions in the first logical page; programming the second parts of the third and fourth portions with the second parts of the first and second portions in the second logical page; programming the third parts of the first, second, third and fourth portions from the third row of data latches in a third logical page in the non-volatile memory cells along the target word line; and programming the fourth parts of the first, second, third and fourth portions from the fourth row of data latches in a fourth logical page in the non-volatile memory cells along the target word line. The method may further include subsequently receiving a read command directed to only the first portion of ECC encoded data; reading the first part of the first portion in a first logical page read operation; and reading the second part of the first portion in a second logical page read operation. The first part of the first portion may be in a first plane, the second part of the first portion may be in a second plane and the first and second logical page read operations may occur in parallel in the first and second planes. The first logical page read operation may include reading at a first plurality of read voltages, the second logical page read operation may include reading at a second plurality of read voltages, no read voltage of the first plurality of read voltages may be equal to any read voltage of the second plurality of read voltages. The first logical page may have a lower error rate than the second logical page and the first and second parts of the first portion that are read in the first and second logical page read operations may have a combined error rate between error rates of the first and second logical pages.

An example of a data storage system includes a plurality of non-volatile memory cells configured to store a plurality of logical pages, the plurality of non-volatile memory cells coupled to a plurality of word lines; and means for scrambling a plurality of encoded portions of data prior to programming the plurality of encoded portions of data in the plurality of logical pages in the plurality of non-volatile memory cells such that each encoded portion is distributed among the plurality of logical pages. The plurality of logical pages may be associated with a corresponding plurality of error rates that are not equal and each of the plurality of encoded portions of data may have an error rate that is an average of the plurality of error rates corresponding to the plurality of logical pages when read from the plurality of non-volatile memory cells.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of non-volatile memory cells arranged along word lines,
the one or more control circuits are configured to:
receive a plurality of encoded portions of data to be programmed in non-volatile memory cells of a target word line, each encoded portion of data encoded according to an Error Correction Code (ECC) encoding scheme,
arrange the plurality of encoded portions of data in a plurality of rows of data latches corresponding to a plurality of logical pages such that each encoded portion of data is distributed across two or more rows of data latches, and
program the distributed encoded portions of data from the plurality of rows of data latches into non-volatile memory cells along a target word line.

2. The apparatus of claim 1 wherein:
the one or more control circuits are further configured to divide each encoded portion of data into a plurality of parts of equal size, each part arranged in a different row of latches.

3. The apparatus of claim 1, wherein:
non-volatile memory cells of the target word line are configured to store n logical pages of data, the plurality of encoded portions of data consists of n encoded portions each equal in size to one logical page; and
the one or more control circuits are further configured to program part of each encoded portion of data in each logical page of non-volatile memory cells of the target word line.

4. The apparatus of claim 1, wherein:
the one or more control circuits are further configured to distribute each encoded portion of data across the plurality rows of data latches as each encoded portion of data is received.

5. The apparatus of claim 1, wherein:
the one or more control circuits are further configured to initially arrange each of the plurality of encoded portions of data in a respective row of data latches and subsequently scramble the plurality of encoded portions of data such that each encoded portion of data is distributed across the plurality of rows of data latches.

6. The apparatus of claim 5, wherein:
the one or more control circuits are further configured to scramble the plurality of encoded portions of data by rotating parts of the plurality of encoded portions of data between rows of data latches.

7. The apparatus of claim 6, wherein;
the one or more control circuits are further configured to rotate parts of the plurality of encoded portions for two or more planes in series.

8. The apparatus of claim 6, wherein;
the one or more control circuits are further configured to rotate parts of the plurality of encoded portions for two or more planes in parallel.

9. The apparatus of claim 6, wherein;
the one or more control circuits, the plurality of rows of data latches and the plurality of non-volatile memory cells are located in a memory die.

10. The apparatus of claim 1 wherein;
the one or more control circuits are further configured to receive a read command directed to an encoded portion of data in the non-volatile memory cells along the target word line and read of the encoded portion by reading at least a first part of the encoded portion in a first logical page using a first set of read voltages and a second part of the encoded portion in a second logical page using a second set of read voltages.

11. The apparatus of claim 9, wherein;
the plurality of encoded portions of data consists of four ECC codewords;
the plurality of rows of data latches includes first, second, third, and fourth rows of data latches corresponding respectively to lower, middle, upper and top pages; and
the one or more control circuits are further configured to arrange each ECC codeword so that for each ECC codeword a first part is in the first row, a second part is in the second row, a third part is in the third row, and a fourth part is in the fourth row.

12. A method comprising:
receiving at least a first portion and a second portion of Error Correction Code (ECC) encoded data for storage in a plurality of logical pages in non-volatile memory cells along a target word line of a memory structure, each portion of ECC encoded data representing a minimum ECC unit;
latching the first portion in a first row of data latches;
latching the second portion in a second row of data latches;
scrambling the first and second portions such that the first row of data latches contains a first part of the first portion and a first part of the second portion and the second row of data latches contains a second part of the first portion and a second part of the second portion;
programming first parts of the first and second portions from the first row to a first logical page in the non-volatile memory cells along the target word line; and
programming second parts of the first and second portions from the second row to a second logical page in the non-volatile memory cells along the target word line.

13. The method of claim 12 further comprising:
receiving a third portion and a fourth portion of ECC encoded data for storage in the plurality of logical pages; and
scrambling the third and fourth portions with the first and second portions such that the first row of data latches additionally contains a first part of the third portion and a first part of the fourth portion, the second row additionally contains a second part of the third portion and a second part of the fourth portion, a third row of data latches contains a third part of each of the first, second, third, and fourth portions, and a fourth row of data latches contains a fourth part of each of the first, second, third, and fourth portions.

14. The method of claim 13 further comprising:
programming the first parts of the third and fourth portions with the first parts of the first and second portions in the first logical page;
programming the second parts of the third and fourth portions with the second parts of the first and second portions in the second logical page;
programming the third parts of the first, second, third and fourth portions from the third row of data latches in a third logical page in the non-volatile memory cells along the target word line; and
programming the fourth parts of the first, second, third and fourth portions from the fourth row of data latches in a fourth logical page in the non-volatile memory cells along the target word line.

15. The method of claim 12 further comprising:
subsequently receiving a read command directed to only the first portion of ECC encoded data;
reading the first part of the first portion in a first logical page read operation; and
reading the second part of the first portion in a second logical page read operation.

16. The method of claim 15 wherein the first part of the first portion is in a first plane, the second part of the first portion is in a second plane and the first and second logical page read operations occur in parallel in the first and second planes.

17. The method of claim 16 wherein the first logical page read operation includes reading at a first plurality of read voltages, the second logical page read operation includes reading at a second plurality of read voltages, no read voltage of the first plurality of read voltages is equal to any read voltage of the second plurality of read voltages.

18. The method of claim 15 wherein the first logical page has a lower error rate than the second logical page and wherein the first and second parts of the first portion that are read in the first and second logical page read operations have a combined error rate between error rates of the first and second logical pages.

19. A data storage system comprising:
a plurality of non-volatile memory cells configured to store a plurality of logical pages, the plurality of non-volatile memory cells coupled to a plurality of word lines; and
means for scrambling a plurality of encoded portions of data prior to programming the plurality of encoded portions of data in the plurality of logical pages in the plurality of non-volatile memory cells such that each encoded portion is distributed among the plurality of logical pages.

20. The data storage system of claim 19, wherein the plurality of logical pages are associated with a corresponding plurality of error rates that are not equal and each of the plurality of encoded portions of data has an error rate that is an average of the plurality of error rates corresponding to the plurality of logical pages when read from the plurality of non-volatile memory cells.
